(19) United States
(12) Patent Application Publication
(10) Pub. No.: US 2024/0170922 A1
(43) Pub. Date: May 23, 2024

(54) SEMICONDUCTOR LASER, ELECTRONIC APPARATUS, AND METHOD FOR MANUFACTURING SEMICONDUCTOR LASER

(71) Applicant: SONY GROUP CORPORATION, TOKYO (JP)

(72) Inventors: YUTA ISOZAKI, KUMAMOTO (JP); YUICHIRO KIKUCHI, KUMAMOTO (JP); HIDEKAZU KAWANISHI, TOKYO (JP); TAKASHI MIZUNO, KUMAMOTO (JP); SHINSUKE NOZAWA, KUMAMOTO (JP)

(21) Appl. No.: 18/551,023

(22) PCT Filed: Jan. 21, 2022
(86) PCT No.: PCT/JP2022/002106

§ 371 Date: Sep. 18, 2023

(30) Foreign Application Priority Data
Mar. 26, 2021 (JP) 2021-053033

(51) Int. Cl. H01S 5/22; H01S 5/10

(52) U.S. Cl. CPC H01S 5/22; H01S 5/1064

(57) ABSTRACT

The present technology provides a semiconductor laser capable of suppressing a decrease in yield while suppressing an influence on laser characteristics. The semiconductor laser according to the present technology includes a resonator having a multilayer structure including: a first cladding layer; a second cladding layer; and an active layer disposed between the first cladding layer and the second cladding layer, the multilayer structure including a pair of resonator end surfaces facing each other. The resonator has a ridge structure extending in a resonator length direction on a surface on a second cladding layer side. A plurality of grooves is provided in at least one of one side portion or the other side portion sandwiching the ridge structure in plan view on the surface of the resonator on the second cladding layer side.

### TECHNICAL FIELD

The technology according to the present disclosure (hereinafter also referred to as “the present technology”) relates to a semiconductor laser, an electronic apparatus, and a method for manufacturing a semiconductor laser.

### BACKGROUND ART

Conventionally, a semiconductor laser including a resonator having a ridge structure is known. Some of such semiconductor lasers have a step confinement layer in a resonator (see, for example, Patent Document 1).

### CITATION LIST

### Patent Document

Patent Document 1: Japanese Patent Application Laid-Open No. 2010-93128

### SUMMARY OF THE INVENTION

### Problems to be Solved by the Invention

However, in the conventional semiconductor laser, there is room for improvement in suppressing a decrease in yield while suppressing an influence on laser characteristics.

Therefore, a main object of the present technology is to provide a semiconductor laser capable of suppressing a decrease in yield while suppressing an influence on laser characteristics.

### Solutions to Problems

The present technology provides a semiconductor laser including a resonator having a multilayer structure including:
a first cladding layer;
a second cladding layer; and
an active layer disposed between the first cladding layer and the second cladding layer,
the multilayer structure including a pair of resonator end surfaces facing each other,
the resonator having a ridge structure extending in a resonator length direction on a surface on a second cladding layer side, and
a plurality of grooves being provided in at least one of one side portion or the other side portion sandwiching the ridge structure in plan view in the surface of the resonator on the second cladding layer side.

The plurality of grooves may be arranged in a direction intersecting the resonator length direction.

Each of the plurality of grooves may extend substantially parallel to the resonator length direction.

The plurality of grooves may be provided in at least part of at least one of the one side portion or the other side portion in the resonator length direction.

The plurality of grooves may include the groove provided at least in a portion of at least one of the one side portion or the other side portion including a position of one of the pair of resonator end surfaces.

The plurality of grooves may include the groove provided at least in a portion of at least one of the one side portion or the other side portion including a position of the other of the pair of resonator end surfaces.

A plurality of first grooves, which is the plurality of grooves, may be provided in the one side portion, and at least two of the plurality of first grooves may have different widths and/or depths.

The at least two first grooves may be narrower as being closer to the ridge structure.

The at least two first grooves may be shallower as being closer to the ridge structure.

The at least two first grooves may be narrower and shallower as being closer to the ridge structure.

A plurality of second grooves, which is the plurality of grooves, may be provided in the other side portion, and at least two of the plurality of second grooves may have different widths and/or depths.

The at least two second grooves may be narrower as being closer to the ridge structure.

The at least two second grooves may be shallower as being closer to the ridge structure.

The at least two second grooves may be narrower and shallower as being closer to the ridge structure.

The resonator may have a first protective structure extending in the resonator length direction on a side of the one side portion opposite to a ridge structure side, and a second protective structure extending in the resonator length direction on a side of the other side portion opposite to a ridge structure side.

The semiconductor laser may include a plurality of the resonators.

The present invention also provides an electronic apparatus including the semiconductor laser.

The present invention also provides a method for manufacturing a semiconductor laser, the method including:
a process of laminating a first cladding layer, an active layer, and a second cladding layer in this order on a substrate to generate a multilayer body;
a process of forming at least a ridge structure on a surface of the multilayer body on a second cladding layer side by etching the multilayer body; and
a process of forming a plurality of grooves in at least one of one side portion or the other side portion sandwiching the ridge structure in plan view in the surface of the multilayer body on the second cladding layer side; and
a process of forming an emission end surface orthogonal to a longitudinal direction of the ridge structure on the multilayer body in which the plurality of grooves is formed.

In the process of forming the plurality of grooves, widths and/or depths of at least two grooves of the plurality of grooves may be made different from each other.

In the process of forming at least the ridge structure, a first protective structure extending in the longitudinal direction on a side of the one side portion opposite to a ridge structure side, and a second protective structure extending in the longitudinal direction on a side of the other side portion opposite to a ridge structure side may also be formed.

### BRIEF DESCRIPTION OF DRAWINGS

FIG. 1 is a cross-sectional view (part 1) illustrating a configuration of a semiconductor laser according to a first embodiment of the present technology.

FIG. 2 is a cross-sectional view (part 2) illustrating the configuration of the semiconductor laser according to the first embodiment of the present technology.

FIG. 3 is a plan view illustrating the configuration of the semiconductor laser according to the first embodiment of the present technology.

FIG. 4 is a flowchart for describing a first example of a method for manufacturing the semiconductor laser according to the first embodiment of the present technology.

FIG. 5 is a flowchart for describing fault suppression groove generation processing 1 (fifth process in FIG. 4).

FIG. 6 is a cross-sectional view illustrating a first process in FIG. 4.

FIG. 7 is a cross-sectional view illustrating a first sub process in a second process in FIG. 4.

FIG. 8 is a cross-sectional view illustrating a second sub process in the second process in FIG. 4.

FIG. 9 is a cross-sectional view illustrating a third sub process in the second process in FIG. 4.

FIG. 10 is a cross-sectional view illustrating a third process in FIG. 4.

FIG. 11 is a cross-sectional view illustrating a first sub process in a fourth process in FIG. 4.

FIG. 12 is a cross-sectional view illustrating a second sub process in the fourth process in FIG. 4.

FIG. 13 is a cross-sectional view illustrating a third sub process in the fourth process in FIG. 4.

FIG. 14 is a cross-sectional view illustrating a first process in FIG. 5.

FIG. 15 is a cross-sectional view illustrating a second process in FIG. 5.

FIG. 16 is a cross-sectional view illustrating a third process in FIG. 5.

FIG. 17 is a cross-sectional view illustrating a sixth process in FIG. 4.

FIG. 18 is a cross-sectional view illustrating a seventh process in FIG. 4.

FIG. 19 is a cross-sectional view illustrating a first sub process in an eighth process in FIG. 4.

FIG. 20 is a cross-sectional view illustrating a second sub process in the eighth process in FIG. 4.

FIG. 21 is a cross-sectional view illustrating a third sub process in the eighth process in FIG. 4.

FIG. 22 is a cross-sectional view illustrating a ninth process in FIG. 4.

FIG. 23 is a flowchart for describing a second example of the method for manufacturing the semiconductor laser according to the first embodiment of the present technology.

FIG. 24 is a flowchart for describing fault suppression groove generation processing 2 (fifth process in FIG. 23).

FIG. 25 is a cross-sectional view illustrating a first process in FIG. 24.

FIG. 26 is a cross-sectional view illustrating a second process in FIG. 24.

FIG. 27 is a cross-sectional view illustrating a third process in FIG. 24.

FIG. 28 is a cross-sectional view illustrating a fourth process in FIG. 24.

FIG. 29 is a cross-sectional view illustrating a fifth process in FIG. 24.

FIG. 30 is a cross-sectional view illustrating a sixth process in FIG. 24.

FIG. 31 is a cross-sectional view illustrating a seventh process in FIG. 24.

FIG. 32 is a cross-sectional view illustrating an eighth process in FIG. 24.

FIG. 33 is a cross-sectional view illustrating a ninth process in FIG. 24.

FIG. 34 is a cross-sectional view illustrating a configuration of a semiconductor laser according to a second embodiment of the present technology.

FIG. 35 is a cross-sectional view illustrating a configuration of a semiconductor laser according to a third embodiment of the present technology.

FIG. 36 is a cross-sectional view illustrating a configuration of a semiconductor laser according to a fourth embodiment of the present technology.

FIG. 37 is a cross-sectional view illustrating a configuration of a semiconductor laser according to a fifth embodiment of the present technology.

FIG. 38 is a cross-sectional view illustrating a configuration of a semiconductor laser according to a sixth embodiment of the present technology.

FIG. 39 is a cross-sectional view illustrating a configuration of a semiconductor laser according to a seventh embodiment of the present technology.

FIG. 40 is a plan view of a resonator of a semiconductor laser according to modification 1 of the present technology.

FIG. 41 is a plan view of a resonator of a semiconductor laser according to modification 2 of the present technology. FIG. 42 is a cross-sectional view illustrating a configuration of a semiconductor laser of a comparative example.

FIG. 43 is a diagram illustrating an application example of the semiconductor laser according to the first embodiment of the present technology to a distance measuring device.

FIG. 44 is a block diagram illustrating an example of schematic configuration of a vehicle control system.

FIG. 45 is an explanatory view illustrating an example of an installation position of the distance measuring device.

### MODE FOR CARRYING OUT THE INVENTION

Hereinafter, preferred embodiments of the present technology will be described in detail with reference to the accompanying drawings. Note that in the present description and the drawings, components having substantially the same functional configuration are denoted by the same reference signs, and redundant descriptions are omitted. The embodiments described below illustrate representative embodiments of the present technology, and the scope of the present technology is not narrowly interpreted by these embodiments. In the present description, even in a case where it is described that a semiconductor laser, an electronic apparatus, and a method for manufacturing a semiconductor laser according to the present technology exhibit a plurality of effects, it is sufficient if the semiconductor laser, the electronic apparatus, and the method for manufacturing a semiconductor laser according to the present technology exhibit at least one effect. The effects described herein are merely examples and are not limited, and other effects may be provided.

Furthermore, description will be given in the following order.
1. Introduction
2. Semiconductor laser according to first embodiment of present technology
(1) Configuration of semiconductor laser
(2) Operation of semiconductor laser
(3) First example of method for manufacturing semiconductor laser
(4) Second example of method for manufacturing semiconductor laser
(5) Effects of semiconductor laser and method for manufacturing the same
3. Semiconductor laser according to second embodiment of present technology
4. Semiconductor laser according to third embodiment of present technology
5. Semiconductor laser according to fourth embodiment of present technology
6. Semiconductor laser according to fifth embodiment of present technology
7. Semiconductor laser according to sixth embodiment of present technology
8. Semiconductor laser according to seventh embodiment of present technology
9. Modifications of present technology
10. Application example to electronic apparatus
11. Example in which semiconductor laser is applied to distance measuring device
12. Example in which distance measuring device is mounted on mobile body

### 1. Introduction

In recent years, a semiconductor laser including a resonator having a ridge structure has been actively developed. It is desirable that the ridge structure has a height as low as possible in order to reduce DC resistance, and a side surface along the longitudinal direction as close to vertical as possible in order to reduce leakage current.

However, particularly in the ridge structure in which the side surface is nearly vertical, when a resonator end surface is formed by, for example, cleavage, dicing, etching, or the like, the width of the resonator end surface sharply changes near a skirt portion of the ridge structure, so that stress tends to concentrate on the skirt portion, and a minute fault (step) of several μm or less from the skirt portion tends to occur (see reference sign F in FIG. 42). If this fault extends to a light emitting region of an active layer, reliability is reduced, so that a yield is reduced.

Therefore, as a result of intensive studies, the inventors have developed a semiconductor laser according to each embodiment and each modification of the present technology as a semiconductor laser capable of suppressing the occurrence of such a fault (step) and eventually suppressing a decrease in yield.

Hereinafter,

### 2. Semiconductor Laser According to First Embodiment of Present Technology

Hereinafter, a semiconductor laser according to a first embodiment will be described with reference to the drawings.

### (1) Configuration of Semiconductor Laser

### (Overall Configuration)

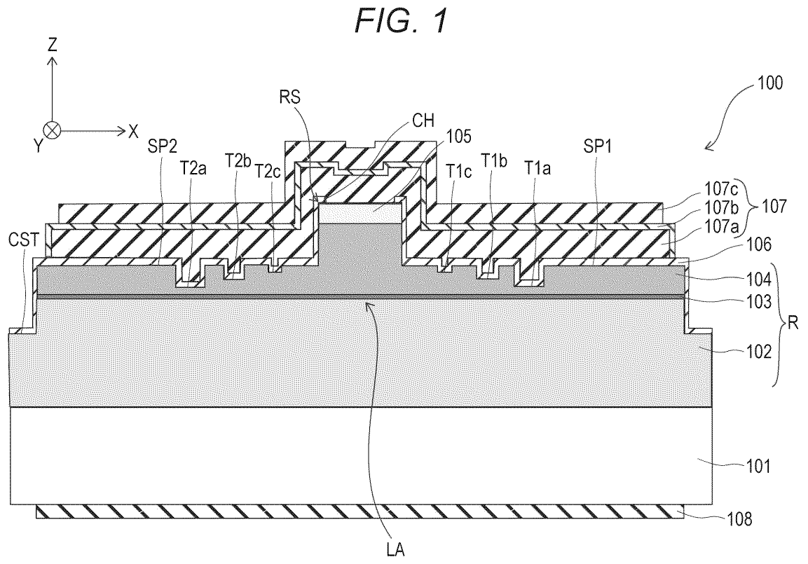

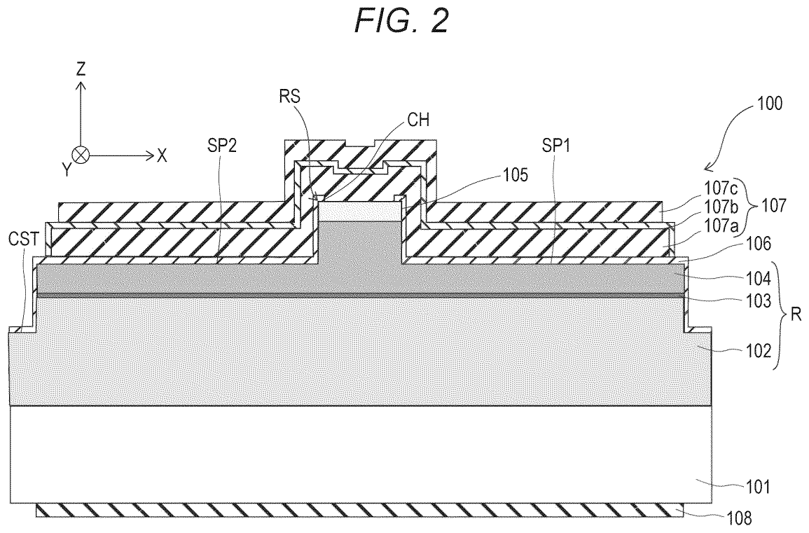

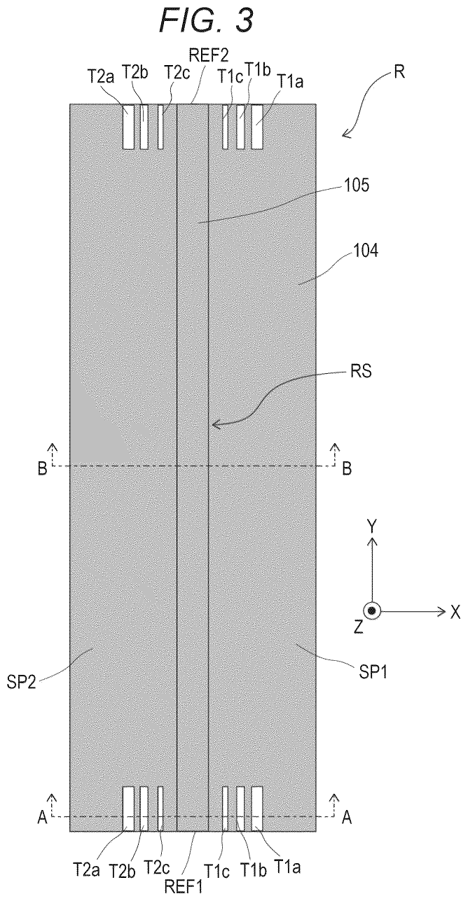

FIG. 1 is a cross-sectional view (part 1) illustrating a configuration of a semiconductor laser 100 according to a first embodiment of the present technology. FIG. 2 is a cross-sectional view (part 2) illustrating the configuration of the semiconductor laser 100 according to the first embodiment of the present technology. FIG. 3 is a plan view of a resonator of the semiconductor laser 100 according to the first embodiment of the present technology. A cross section A-A of FIG. 3 is a cross section of the resonator of the semiconductor laser illustrated in FIG. 1. A cross section B-B of FIG. 3 is a cross section of the resonator of the semiconductor laser illustrated in FIG. 2.

Hereinafter, the description will be given by using an XYZ three-dimensional orthogonal coordinate system illustrated in FIGS. 1 to 3 as appropriate. Moreover, the description will be appropriately given assuming that the +Z side is an upper side and the −Z side is a lower side.

The semiconductor laser 100 is an end surface emission type semiconductor laser. Here, a GaN-based end surface emission type semiconductor laser will be described as an example of the semiconductor laser 100.

As an example, the semiconductor laser 100 includes a resonator R as illustrated in FIGS. 1 and 2.

The resonator R has a multilayer structure including a first cladding layer 102, a second cladding layer 104, and an active layer 103 disposed between the first cladding layer 102 and the second cladding layer 104.

In the multilayer structure, the first cladding layer 102, the active layer 103, and the second cladding layer 104 are laminated in this order from the −Z side to the +Z side.

As illustrated in FIG. 3, the multilayer structure has a pair of resonator end surfaces REF1 and REF2 facing each other. The pair of resonator end surfaces REF1 and REF2 faces each other in the Y-axis direction. The lamination direction in the multilayer structure coincides with the Z-axis direction.

Returning to FIG. 1, the resonator R is disposed on a substrate 101. The surface of the resonator R on the second cladding layer 104 side is covered with an insulating layer 106. A contact hole CH is formed at a location corresponding to a top portion (for example, a transparent conductive film 105) of the ridge structure RS in the insulating layer 106.

An anode electrode 107 is provided on the insulating layer 106. The anode electrode 107 is in contact with the top portion (for example, the transparent conductive film 105) of the ridge structure RS via the contact hole CH. The anode electrode 107 is connected to an anode (positive electrode) of a laser driver.

A cathode electrode 108 is provided on the back surface (surface on the −Z side) of the substrate 101. The cathode electrode 108 is electrically connected to a cathode (negative electrode) of the laser driver.

As can be seen from FIGS. 1 to 3 all together, the resonator R has the ridge structure RS on the surface on the second cladding layer 104 side (+Z side), the ridge structure RS extending in the resonator length direction (Y-axis direction), which is a direction orthogonal to each of the resonator end surfaces. The ridge structure RS forms an elongated and projecting optical waveguide. The longitudinal direction of the ridge structure RS coincides with the resonator length direction (Y-axis direction).

As an example, the ridge structure RS includes the second cladding layer 104 and the transparent conductive film 105 disposed on a side (+Z side) of the second cladding layer 104 opposite to the active layer 103 side (−Z side).

The ridge structure RS has a function of constricting a current flowing in from the anode electrode 107 and guiding the current to the active layer 103.

The ridge structure RS preferably has a height as low as possible in order to reduce DC resistance.

It is desirable that the side surface of the ridge structure RS along the longitudinal direction is as close to vertical as possible in order to reduce leakage current; however, the side surface may be slightly inclined.

The width of the ridge structure RS in the direction (X-axis direction) orthogonal to the resonator length direction is preferably, for example, 0.5 μm to 100 μm, and is set to, for example, 40 μm here.

The length of the ridge structure RS in the resonator length direction (Y-axis direction) is preferably, for example, 50 μm to 3000 μm, and is set to, for example, 1200 μm here.

Chip separation grooves CST (grooves for chip separation) are provided in a side surface (+X-side surface) of one side portion SP1 (+X-side portion) of the surface of the resonator R on the second cladding layer 104 side and a side surface (−X-side surface) of the other side portion SP2 (−X-side portion) of the surface of the resonator R on the second cladding layer 104 side, the one side portion and the other side portion sandwiching the ridge structure RS in plan view. The bottom surface of each chip separation groove CST is located, for example, in the first cladding layer 102.

A plurality of (for example, three) grooves T1a, T1b, T1c is provided in the one side portion SP1 of the surface of the resonator R on the second cladding layer 104 side, and a plurality of (for example, three) grooves T2a, T2b, T2c is provided in the other side portion SP2 of the surface of the resonator R on the second cladding layer 104 side (see FIGS. 1 and 3). Hereinafter, each groove is also referred to as a “fault suppression groove”.

### (Substrate)

The substrate 101 is, for example, an n-type GaN substrate (for example, a GaN free-standing substrate).

(Active layer)

As an example, the active layer 103 has a quantum well structure including a barrier layer including a GaN-based compound semiconductor and a quantum well layer. This quantum well structure may be a single quantum well structure (QW structure) or a multiple quantum well structure (MQW structure).

A region of the active layer 103 corresponding to the ridge structure RS (specifically, a region on the −Z side of the ridge structure RS and into which a current is injected) is a light emitting region LA.

### (First Cladding Layer)

As an example, the first cladding layer 102 includes an n-type GaN layer including an n-type cladding layer and an n-type guide layer. The n-type guide layer is disposed between the n-type cladding layer and the active layer 103.

### (Second Cladding Layer)

As an example, the second cladding layer 104 includes a p-type GaN layer including a p-type cladding layer and a p-type guide layer. The p-type guide layer is disposed between the p-type cladding layer and the active layer 103.

As an example, in the second cladding layer 104, a region from the skirt portion on the +X side to the side surface on the +X side of the ridge structure RS is increased in resistance by ion implantation. In the second cladding layer 104, a region from the skirt portion on the −X side to the side surface on the −X side of the ridge structure RS is increased in resistance by ion implantation. In the ion implantation, for example, boron is used.

That is, the region surrounding the region between the ridge structure RS in the second cladding layer 104 and the active layer 103 is a current constriction region (high resistance region). Therefore, the current flowing from the anode electrode 107 and constricted by the ridge structure RS can be constricted also in the current constriction region and guided to the active layer 103, and the current can be efficiently injected into the active layer 103.

Note that the second cladding layer 104 may have a contact layer including, for example, a p-type GaN layer between the transparent conductive film 105 and the p-type cladding layer.

### (Transparent Conductive Film)

The transparent conductive film 105 includes Indium Tin Oxide (ITO), Indium Titanium Oxide (ITiO), Al₂O₃-ZnO (AZO), InGaZnOx (IGZO), ZnO, or the like, for example. The transparent conductive film 105 has high carrier conductivity, and plays a role of facilitating injection of carriers (for example, holes) flowing in from the anode electrode 107 into the active layer 103 particularly in a GaN-based semiconductor laser.

### (Insulating Layer)

The insulating layer 106 is formed by a dielectric such as SiO₂, SiN, Al₂O₃, AlN, or the like. The thickness of the insulating layer 106 is preferably, for example, 10 nm to 500 nm, and is set to, for example, 200 μm here.

### (Anode Electrode)

As an example, the anode electrode 107 has a layer structure in which a pad metal 107a, a barrier metal 107b, and a bonding metal 107c are laminated. The pad metal 107a is the lowermost layer, the barrier metal 107b is the intermediate layer, and the bonding metal 107c is the uppermost layer.

The pad metal 107a is provided directly on the insulating layer 106 and is in contact with the top portion (for example, the transparent conductive film 105) of the ridge structure RS via the contact hole CH.

The pad metal 107a includes, for example, Ti, Pt, Pd, Ni, Au, or the like. The barrier metal 107b includes, for example, Ti, Pt, Mo, W, or the like. The bonding metal 107c includes, for example, Ti, Pt, or Au.

### (Cathode Electrode)

As an example, the cathode electrode 108 includes V, Ti, Pt, Au, or the like.

### (Fault Suppression Groove)

Each of the fault suppression grooves is a groove that suppresses generation of a fault (step) in the vicinity of the skirt portion of the ridge structure RS at the time of cleavage, dicing, etching, or the like when the resonator end surface as described above is formed.

Hereinafter, the fault suppression grooves T1a to T1c formed in the one side portion SP1 of the surface of the resonator R on the second cladding layer 104 side are also referred to as first grooves T1a to T1c , and the fault suppression grooves T2a to T2c formed in the other side portion SP2 of the surface of the resonator R on the second cladding layer 104 side are also referred to as second grooves T2a to T2c.

As an example, as illustrated in FIGS. 1 and 3, the plurality of (for example, three) first grooves T1a to T1c is arranged in the direction (X-axis direction) orthogonal to the resonator length direction (Y-axis direction) in the one side portion SP1. Note that the plurality of first grooves T1a to T1c is not necessarily arranged in the direction orthogonal to the resonator length direction, and it is sufficient if the first grooves T1a to T1c are arranged in the direction intersecting the resonator length direction.

As an example, as illustrated in FIGS. 1 and 3, the plurality of (for example, three) second grooves T2a to T2c is arranged in the direction (X-axis direction) orthogonal to the resonator length direction (Y-axis direction) in the other side portion SP2. Note that the plurality of second grooves T2a to T2c is not necessarily arranged in the direction orthogonal to the resonator length direction, and it is sufficient if the second grooves T2a to T2c are arranged in the direction intersecting the resonator length direction.

Each of the plurality of first grooves T1a to T1c extends substantially parallel to the resonator length direction (Y-axis direction). Note that at least one of the plurality of first grooves T1a to T1c may extend non-parallel to the resonator length direction.

Each of the plurality of second grooves T2a to T2c extends substantially parallel to the resonator length direction (Y-axis direction). Note that at least one of the plurality of second grooves T2a to T2c may extend non-parallel to the resonator length direction.

As illustrated in FIGS. 1 to 3, the plurality of first grooves T1a to T1c is provided in part of the one side portion SP1 in the resonator length direction (Y-axis direction).

More specifically, the plurality of first grooves T1a to T1c is provided in each of a portion of the one side portion SP1 including the position of the resonator end surface REF1, which is one of the resonator end surfaces (−Y-side end portion of the one side portion SP1) and a portion of the one side portion SP1 including the position of the resonator end surface REF2, which is the other of the resonator end surfaces (+Y-side end portion of the one side portion SP1).

Here, the lengths (lengths in the resonator length direction) of the plurality of first grooves T1a to T1c are the same, but the lengths of at least two first grooves may be different.

As illustrated in FIGS. 1 to 3, the plurality of second grooves T2a to T2c is provided in part of the other side portion SP2 in the resonator length direction (Y-axis direction).

More specifically, the plurality of second grooves T2a to T2c is provided in each of a portion of the other side portion SP2 including the position of the resonator end surface REF1, which is one of the resonator end surfaces (−Y-side end portion of the other side portion SP2) and a portion of the other side portion SP2 including the position of the resonator end surfaces REF2, which is the other of the resonator end surfaces (+Y-side end portion of the other side portion SP2).

Here, the lengths (lengths in the resonator length direction) of the plurality of second grooves T2a to T2c are the same, but the lengths of at least two second grooves may be different.

As illustrated in FIGS. 1 and 3, the plurality of first grooves T1a to T1c has different widths (widths in the X-axis direction) and depths.

Specifically, the plurality of first grooves T1a to T1c is narrower as being closer to the ridge structure RS. More specifically, among the plurality of first grooves T1a to T1c , the first groove T1a is farthest from the ridge structure RS and is widest, and the first groove T1c is closest to the ridge structure RS and is narrowest.

The plurality of first grooves T1a to T1c is shallower as being closer to the ridge structure RS. More specifically, among the plurality of first grooves T1a to T1c , the first groove T1a is farthest from the ridge structure RS and is deepest, and the first groove T1c is closest to the ridge structure RS and is shallowest.

That is, the plurality of first grooves T1a to T1c is narrower and shallower as being closer to the ridge structure RS.

As illustrated in FIGS. 1 and 3, the plurality of second grooves T2a to T2c has different widths (widths in the X-axis direction) and depths.

Specifically, the plurality of second grooves T2a to T2c is narrower as being closer to the ridge structure RS. More specifically, among the plurality of second grooves T2a to T2c, the second groove T2a is farthest from the ridge structure RS and is widest, and the second groove T2c is closest to the ridge structure RS and is narrowest.

The plurality of second grooves T2a to T2c is shallower as being closer to the ridge structure RS. More specifically, among the plurality of second grooves T2a to T2c, the second groove T2a is farthest from the ridge structure RS and is deepest, and the second groove T2c is closest to the ridge structure RS and is shallowest.

That is, the plurality of second grooves T2a to T2c is narrower and shallower as being closer to the ridge structure RS.

Here, it is considered that the wider the groove or the deeper the groove, the higher the stress absorbability, but on the other hand, the groove can be a starting point of a fault due to the great stress absorbed. The groove that can be the starting point of a fault is preferably provided at a location as far as possible from the ridge structure and the light emitting region LA.

Therefore, among the first grooves T1a to T1c , the first groove T1a having the highest stress absorbability is provided at a location farthest from the ridge structure RS, the first groove T1c having the lowest stress absorbability is provided at a location closest to the ridge structure RS, and the first groove T1b having the stress absorbability between those of the first groove T1a and the first groove T1c is provided between the first grooves T1a and T1c.

Similarly, among the second grooves T2a to T2c, the second groove T2a having the highest stress absorbability is provided at a location farthest from the ridge structure RS, the second groove T2c having the lowest stress absorbability is provided at a location closest to the ridge structure RS, and the second groove T2b having the stress absorbability between those of the second groove T2a and the second groove T2c is provided between the second grooves T2a and T2c.

The width of each of the first and second grooves is preferably, for example, 0 to 10 μm, and for example, a plurality of first grooves having different widths and a plurality of second grooves having different widths may be provided with a width of 3 μm, a width of 5 μm, a width of 7 μm, or the like as a median value or an average value.

The depth of each of the first and second grooves is preferably, for example, 0 to 500 nm, and for example, a plurality of first grooves having different depths and a plurality of second grooves having different depths may be provided with a depth of 100 nm, a depth of 200 nm, a depth of 300 nm, or the like as a median value or an average value.

Here, the first and second grooves T1a, T2a farthest from the ridge structure RS have the same width and depth, but may have different widths and/or depths.

Here, the first and second grooves T1c , T2c closest to the ridge structure RS have the same width and depth, but may have different widths and/or depths.

Here, the first groove T1b located between the first groove T1a and the first groove T1c and the second groove T2b located between the second groove T2a and the second groove T2c have the same width and depth, but may have different widths and/or depths.

The plurality of first grooves T1a to T1c may have the same depth and different widths, or may have different depths and the same width. The plurality of second grooves T2a to T2c may have the same depth and different widths, or may have different depths and the same width.

Here, the bottom surfaces of the plurality of first grooves T1a to T1c and the bottom surfaces of the plurality of second grooves T2a to T2c are both located in the second cladding layer 104, but for example, the bottom surface of at least one first groove and/or the bottom surface of at least one second groove may be located in the first cladding layer 102.

### (2) Operation of Semiconductor Laser

Hereinafter, the operation of the semiconductor laser 100 will be described with reference to FIG. 1.

In the semiconductor laser 100, a current flowing from the anode of the laser driver via the anode electrode 107 is injected into the active layer 103 via the transparent conductive film 105 and the second cladding layer 104 (constricted by the ridge structure RS and the current constriction region). At this time, the active layer 103 emits light, and the light reciprocates between the pair of resonator end surfaces REF1 and REF2 along the ridge structure RS while being amplified by the active layer 103, and is emitted to the outside at a predetermined ratio from each of the pair of resonator end surfaces REF1 and REF2 when an oscillation condition is satisfied. The current that has passed through the active layer 103 reaches the cathode electrode 108 via the first cladding layer 102 and the substrate 101, and flows out from the cathode electrode 108 to the cathode of the laser driver.

### (3) First Example of Method for Manufacturing Semiconductor Laser

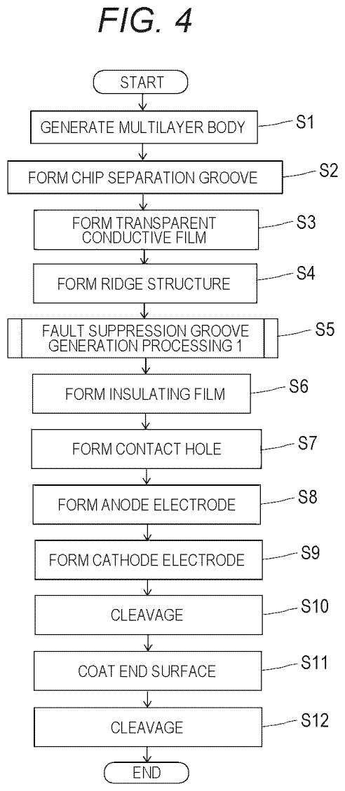

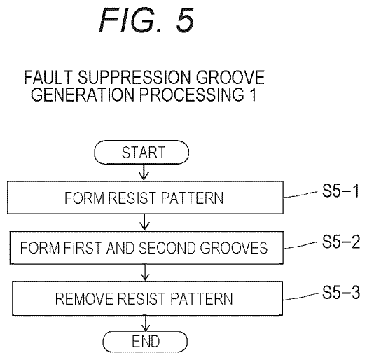

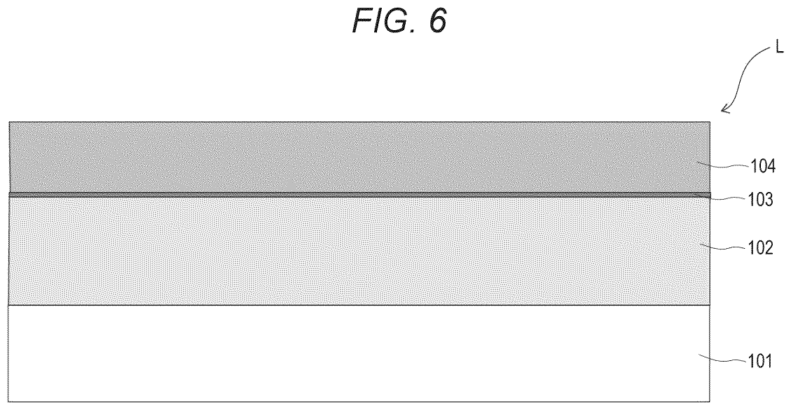

Hereinafter, a first example of a method for manufacturing the semiconductor laser 100 will be described with reference to the flowchart (steps S1 to S12) in FIG. 4, the flowchart in FIG. 5, and the process diagrams in FIGS. 6 to 22. Here, as an example, by a semiconductor manufacturing method using a semiconductor manufacturing device, a plurality of semiconductor lasers 100 is simultaneously generated on one wafer (for example, a GaN substrate) to be a base material of the substrate 101 and separated from each other, thereby obtaining the plurality of semiconductor lasers 100 in a chip shape.

### <Step S1>

In step S1, a multilayer body L is generated (see FIG. 6). Specifically, as an example, the first cladding layer 102, the active layer 103, and the second cladding layer 104 are laminated in this order on the substrate 101 by a chemical vapor deposition (CVD) method, for example, a metal organic chemical vapor deposition (MOCVD) method to generate the multilayer body L.

### <Step S2>

In step S2, the chip separation groove CST is formed.

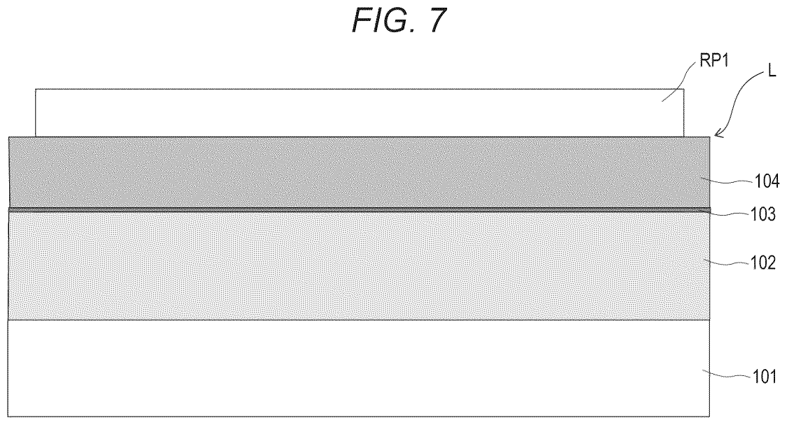

Specifically, first, a resist pattern RP1 including, for example, SiO₂, SiN, or the like is formed on the multilayer body L by a vapor deposition method, a sputtering method, or the like (see FIG. 7). More specifically, the resist pattern RP1 is formed by forming a pattern on a resist film by photolithography, and then removing a resist in a portion to be an opening in the resist film by dry etching by an RIE method using a fluorine-based gas or wet etching using a hydrofluoric acid-based etchant.

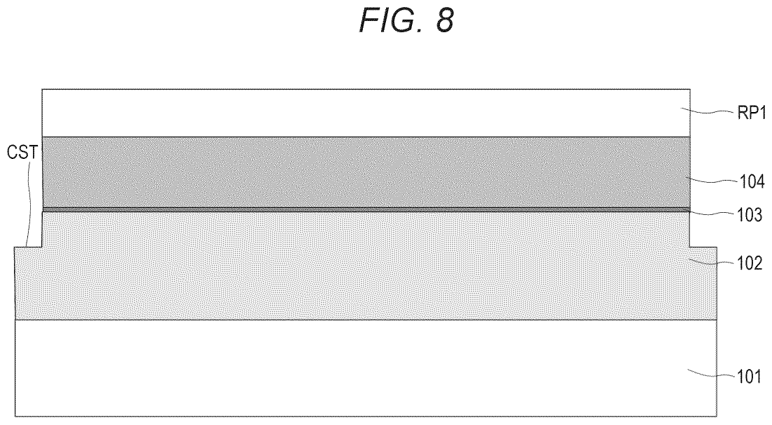

Next, by using the resist pattern RP1 as a mask, the multilayer body L is etched from the second cladding layer 104 side to the inside of the first cladding layer 102 by the reactive ion etching (RIE) method using a chlorine-based gas (see FIG. 8). As a result, the chip separation groove CST is formed.

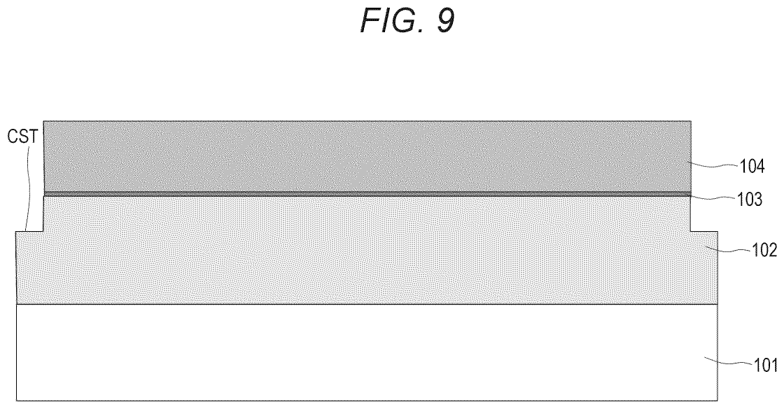

Next, the resist pattern RP1 is removed (see FIG. 9). Specifically, the resist pattern RP1 is removed by dry etching by the RIE method using a fluorine-based gas or wet etching using a hydrofluoric acid-based etchant.

### <Step S3>

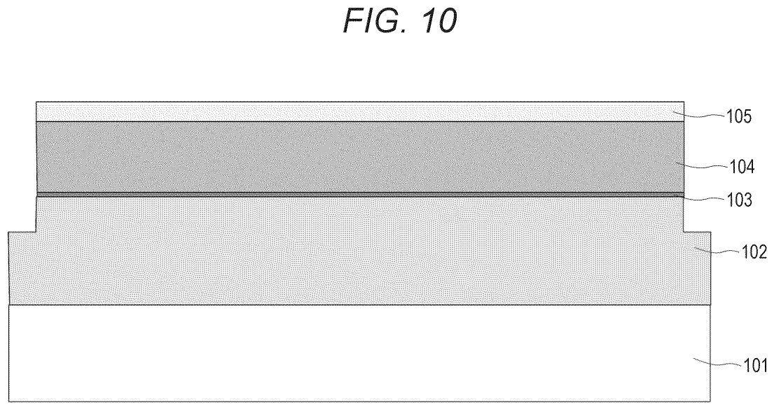

In step S3, the transparent conductive film 105 is formed. Specifically, the transparent conductive film 105 is laminated on the second cladding layer 104 of the multilayer body in which the chip separation groove CST is formed (see FIG. 10).

### <Step S4>

In step S4, the ridge structure RS is formed.

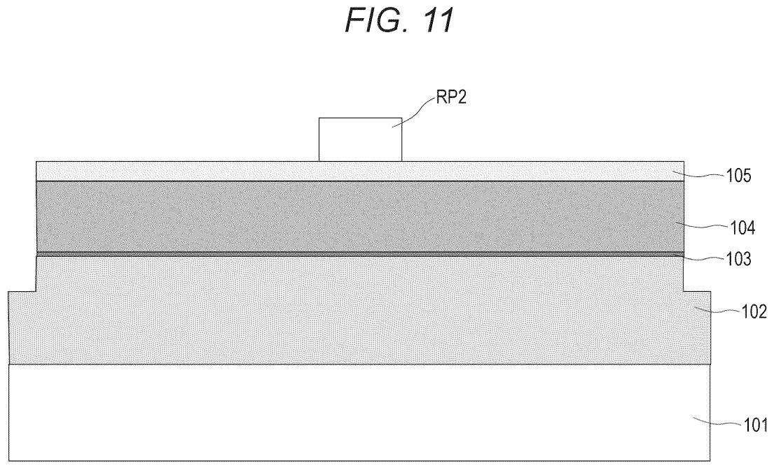

Specifically, first, a resist pattern RP2 is formed at a location on the transparent conductive film 105, the location corresponding to a location where the ridge structure RS of the transparent conductive film 105 and the second cladding layer 104 is to be formed (see FIG. 11). The resist pattern RP2 is formed by a technique similar to that of the resist pattern RP1.

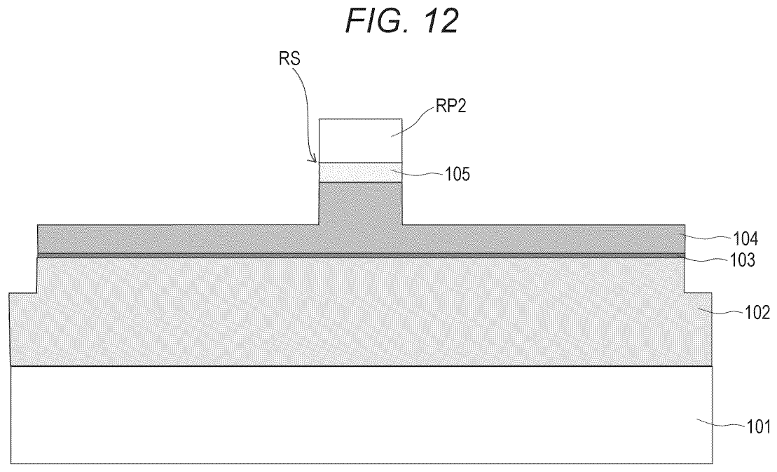

Next, by using the resist pattern RP2 as a mask, at least part (for example, part) of the transparent conductive film 105 and the second cladding layer 104 in the thickness direction is etched by RIE or the like. As a result, the ridge structure RS is formed (see FIG. 12).

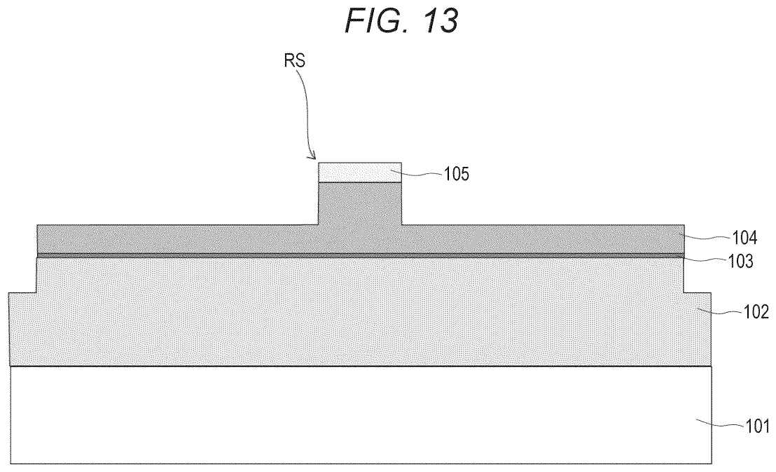

Next, the resist pattern RP2 is removed (see FIG. 13). Specifically, the resist pattern RP2 is removed by dry etching or wet etching similarly to the resist pattern RP1.

### <Step S5>

In step S5, fault suppression groove generation processing 1 (steps S5-1 to S5-3 in FIG. 5) is performed.

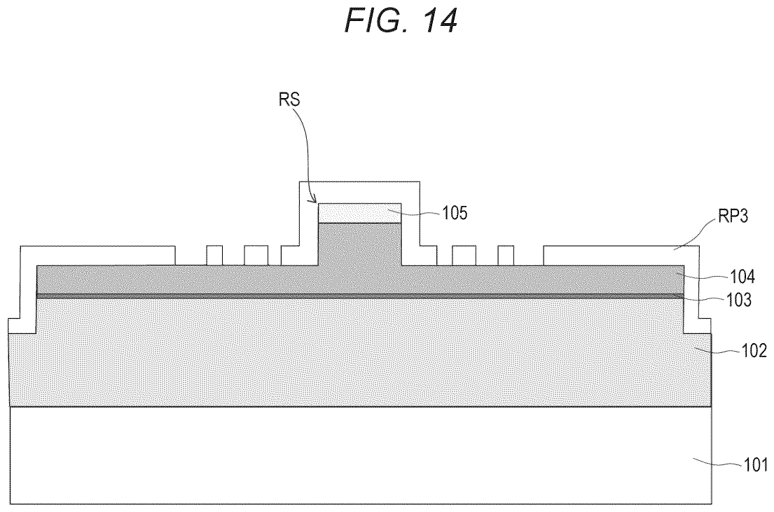

In the first step S5-1, a resist pattern RP3 is formed. Specifically, the resist pattern RP3 is formed on the multilayer body on which the ridge structure RS is formed, the resist pattern RP3 having an opening at a location corresponding to a location where the first grooves T1a to T1c and the second grooves T2a to T2c of the multilayer body are to be formed (see FIG. 14). The resist pattern RP3 is formed by a technique similar to those of the resist patterns RP1 and RP2.

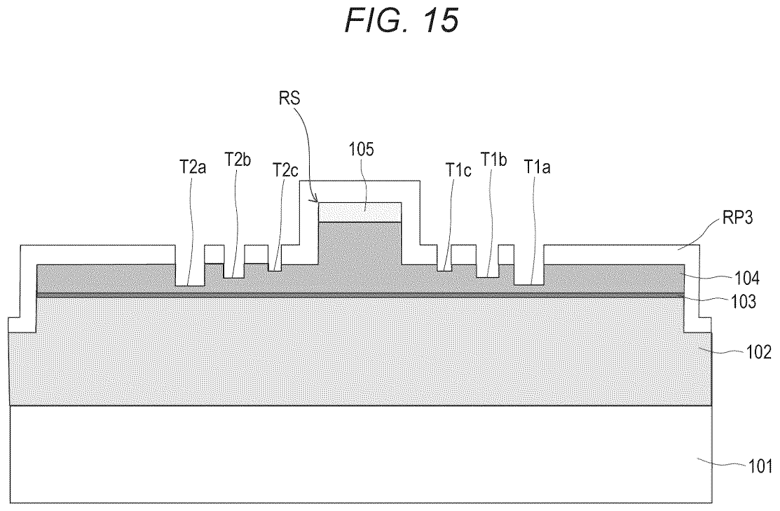

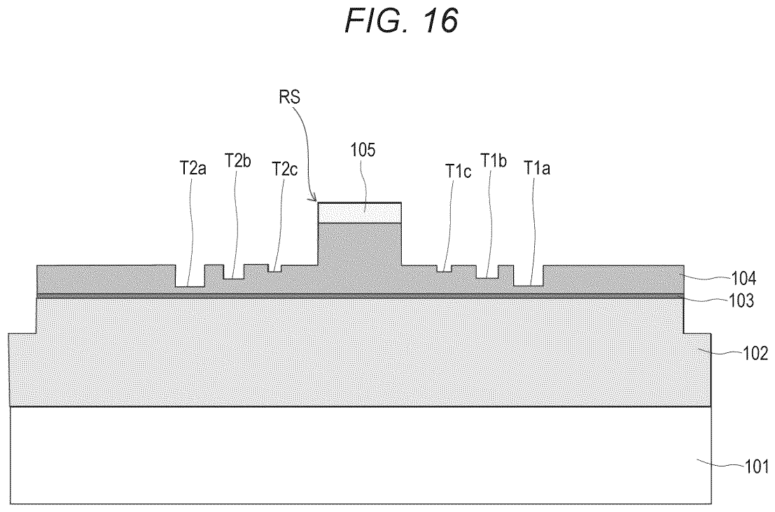

In the next step S5-2, the first grooves T1a to T1c and the second grooves T2a to T2c are formed. Specifically, by using the resist pattern RP3 as a mask, the second cladding layer 104 is etched by the RIE method using a chlorine-based gas to simultaneously form the first grooves T1a to T1c and the second grooves T2a to T2c (see FIG. 15). Here, the first grooves T1a to T1c having different widths and depths and the second grooves T2a to T2c having different widths and depths are simultaneously formed by the microloading effect.

In the last step S5-3, the resist pattern RP3 is removed (see FIG. 16). Specifically, the resist pattern RP3 is removed by dry etching or wet etching similarly to the resist patterns RP1 and RP2.

### <Step S6>

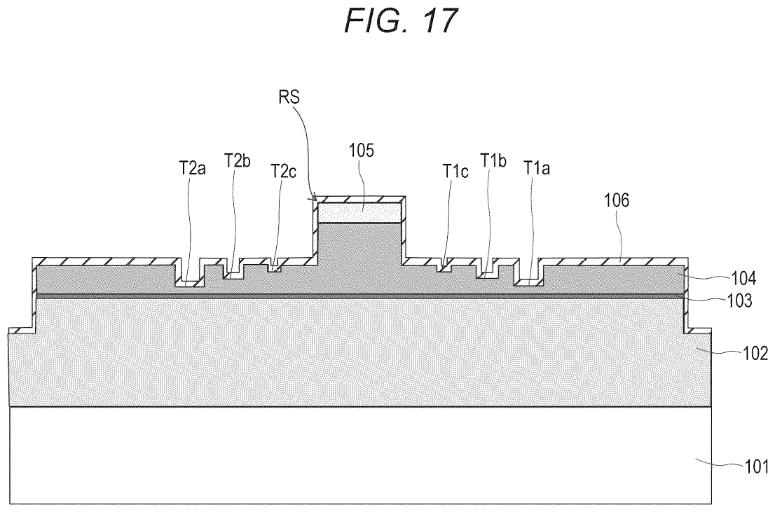

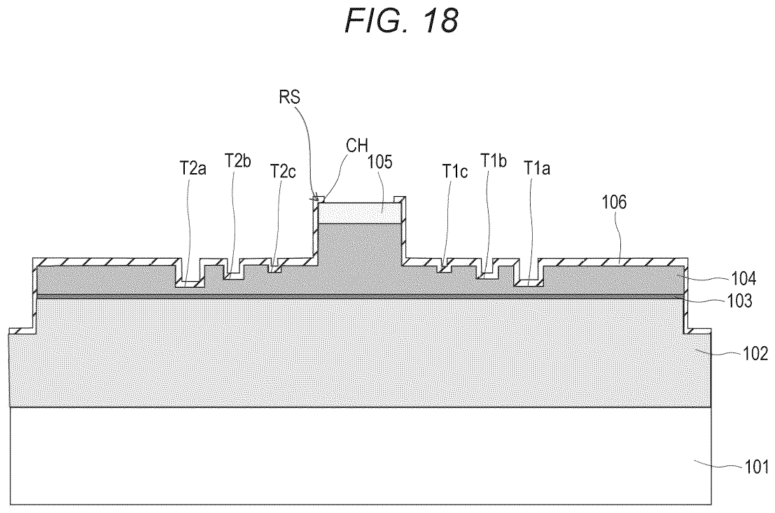

In step S6, the insulating layer 106 is formed. Specifically, the insulating layer 106 is formed on the multilayer body on which the ridge structure RS is formed and in which the first grooves T1a to T1c and the second grooves T2a to T2c are formed by a vapor deposition method, a sputtering method, or the like (see FIG. 17).

### <Step S7>

In step S7, the contact hole CH is formed. Specifically, the insulating layer 106 on the top portion of the ridge structure RS is removed by dry etching by the RIE method using a fluorine-based gas or wet etching using a hydrofluoric acid-based etchant. As a result, the contact hole CH is formed, and the top portion (for example, the transparent conductive film 105) of the ridge structure RS is exposed (see FIG. 18).

### <Step S8>

In step S8, the anode electrode 107 is formed.

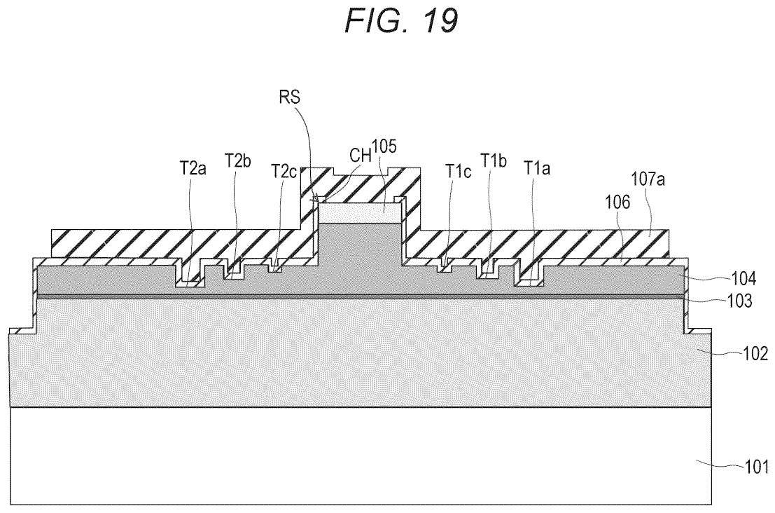

Specifically, first, the pad metal 107a is formed on the insulating layer 106 in which the contact hole CH is opened (see FIG. 19). More specifically, a film of the material of the pad metal 107a is formed by a vapor deposition method, a sputtering method, or the like, and patterning is performed by a lift-off method, for example.

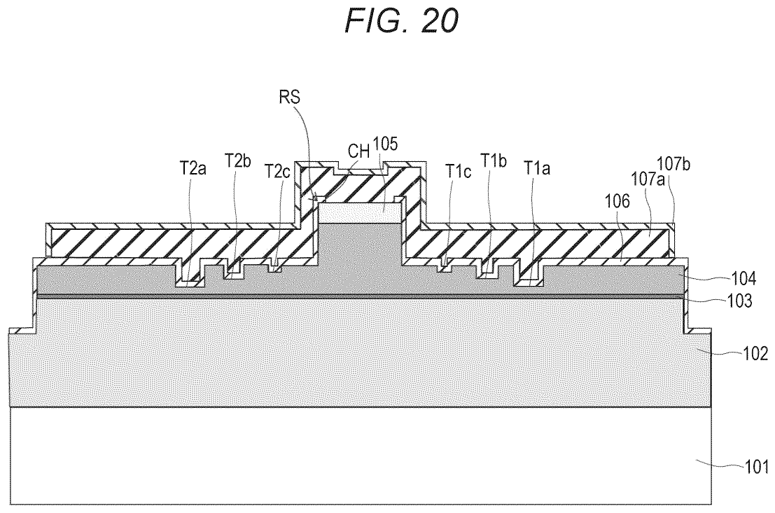

Next, the barrier metal 107b is formed on the pad metal 107a by a similar technique (see FIG. 20).

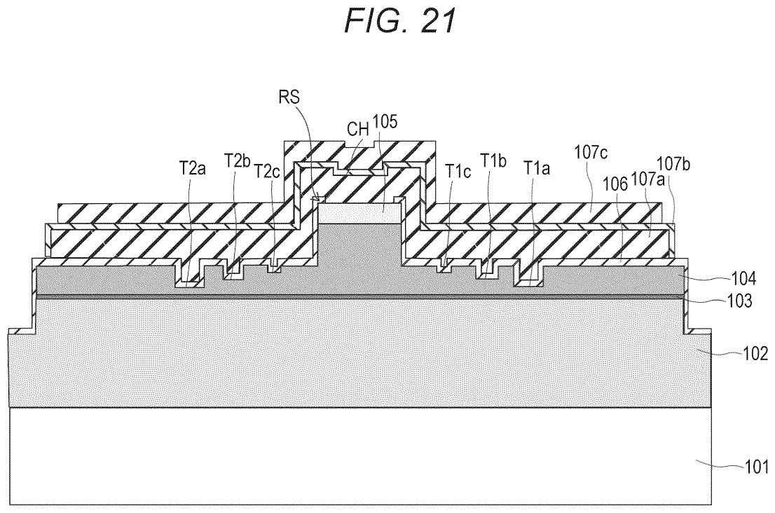

Next, the bonding metal 107c is formed on the barrier metal 107b by a similar technique (see FIG. 21).

### <Step S9>

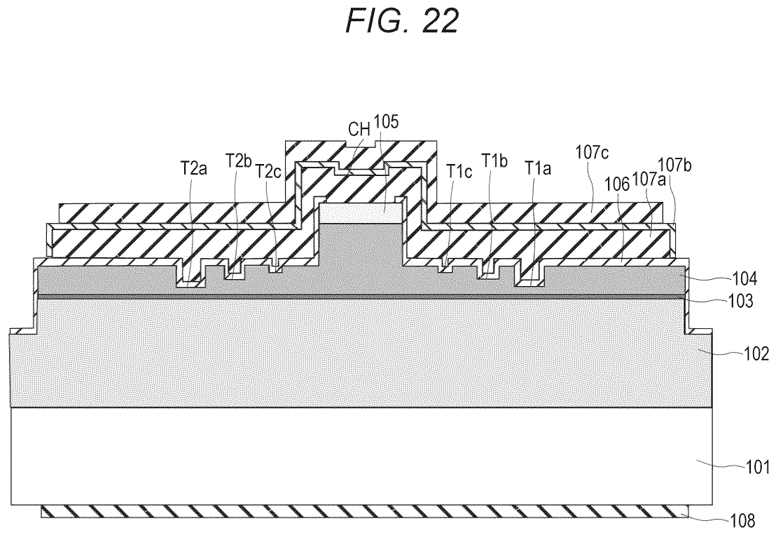

In step S9, the cathode electrode 108 is formed (see FIG. 22).

Specifically, after the back surface of the substrate 101 is polished to a thickness suitable for cleavage, chipping, and mounting, the material of the cathode electrode 108 is formed on the back surface of the substrate 101 by a vapor deposition method or a sputtering method, and patterning is performed by lift-off, for example.

### <Step S10>

In step S10, cleavage is performed. Specifically, cleavage is performed in a bar shape so that the emission end surface (resonator end surface) is exposed.

Specifically, first, a scribe (scratch extending in a direction orthogonal to the longitudinal direction of the ridge structure RS) is periodically (for each resonator length) formed on an end portion of the wafer on which the plurality of semiconductor lasers 100 is formed with a diamond cutter or a laser.

Then, pressure is applied from the back side of the scratched surface, and the scratched portion is divided so as to open. Therefore, the wafer is broken along the crystal direction, and a plurality of bars is obtained. The exposed end surfaces (cleavage plane) of the respective bars become resonator end surfaces (emission end surfaces) of the plurality of semiconductor lasers 100.

Here, at the time of the cleavage described above, stress tends to concentrate on the skirt portion of the ridge structure RS in the vicinity of the cleavage plane due to a sharp change in the area in the vicinity of the skirt portion; however, on the +X side of the ridge structure RS, it is possible to decrease the transmission speed of the stress while greatly absorbing the stress in the outer first groove T1a, it is possible to further decrease the transmission speed of the stress while absorbing the stress in the intermediate first groove T1b, and it is possible to absorb the stress in the inner first groove T1c . Therefore, it is possible to suppress concentration of stress from the +X side on the ridge structure RS, and eventually, it is possible to suppress generation of a fault starting from the skirt portion on the +X side of the ridge structure RS due to the stress.

Also on the −X side of the ridge structure RS, it is possible to reduce the transmission speed of the stress while greatly absorbing the stress in the outer second groove T2a, it is possible to further reduce the transmission speed of the stress while absorbing the stress in the intermediate second groove T2b, and it is possible to absorb the stress in the inner second groove T2c. Therefore, it is possible to suppress concentration of stress from the −X side on the ridge structure RS, and eventually, it is possible to suppress generation of a fault starting from the skirt portion on the −X side of the ridge structure RS due to the stress.

### <Step S11>

In step S11, the end surface is coated. Specifically, the exposed end surface (cleavage plane) of each bar is coated in accordance with device characteristics. More specifically, a dielectric film such as Al₂O₃, Si0₂, or Si₃N₄ is formed with a predetermined thickness on the cleavage plane of each bar by a vapor deposition method or a sputtering method.

### <Step S12>

In step S12, cleavage is performed. Specifically, scribes are formed in the bar along the longitudinal direction of the ridge structure RS and the bar is divided into chips, thereby obtaining the chip-shaped semiconductor laser 100.

### (4) Second Example of Method for Manufacturing Semiconductor Laser

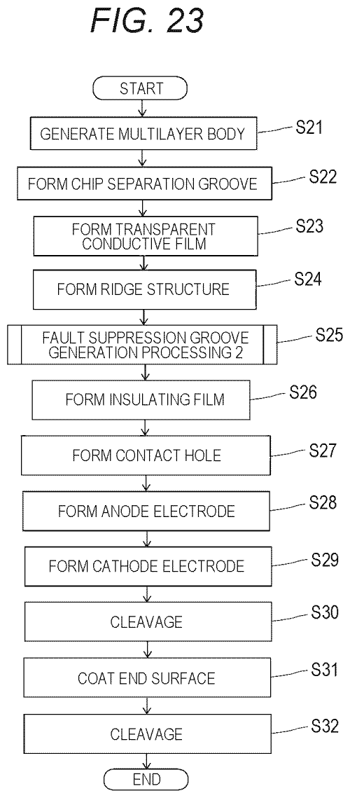

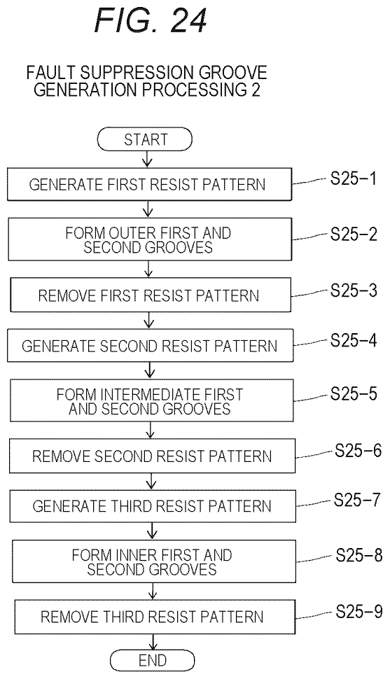

Hereinafter, a second example of the method for manufacturing the semiconductor laser 100 will be described with reference to the flowchart (steps S21 to S32) in FIG. 23, the flowchart in FIG. 24, and the process diagrams in FIGS. 6 to 13, FIGS. 17 to 22, and FIGS. 25 to 33. Here, as an example, by a semiconductor manufacturing method using a semiconductor manufacturing device, a plurality of semiconductor lasers 100 is simultaneously generated on one wafer (for example, a GaN substrate) to be a base material of the substrate 101 and separated from each other, thereby obtaining the plurality of semiconductor lasers 100 in a chip shape.

### <Step S21>

In the first step S21, the multilayer body L is generated (FIG. 6). Specifically, as an example, the first cladding layer 102, the active layer 103, and the second cladding layer 104 are laminated in this order on the substrate 101 by a chemical vapor deposition (CVD) method, for example, a metal organic chemical vapor deposition (MOCVD) method to generate the multilayer body L.

### <Step S22>

In step S22, the chip separation groove CST is formed.

Specifically, first, a resist pattern RP1 including, for example, SiO₂, SiN, or the like is formed on the multilayer body L by a vapor deposition method, a sputtering method, or the like (see FIG. 7). More specifically, the resist pattern RP1 is formed by forming a pattern on a resist film by photolithography, and then removing a resist in a portion to be an opening in the resist film by dry etching by an RIE method using a fluorine-based gas or wet etching using a hydrofluoric acid-based etchant.

Next, by using the resist pattern RP1 as a mask, the multilayer body L is etched from the second cladding layer 104 side to the inside of the first cladding layer 102 by the reactive ion etching (RIE) method using a chlorine-based gas (see FIG. 8). As a result, the chip separation groove CST is formed.

Next, the resist pattern RP1 is removed (see FIG. 9). Specifically, the resist pattern RP1 is removed by dry etching by the RIE method using a fluorine-based gas or wet etching using a hydrofluoric acid-based etchant.

### <Step S23>

In step S13, the transparent conductive film 105 is formed. Specifically, the transparent conductive film 105 is laminated on the second cladding layer 104 of the multilayer body in which the chip separation groove CST is formed (see FIG. 10).

### <Step S24>

In step S14, the ridge structure RS is formed.

Specifically, first, a resist pattern RP2 is formed at a location on the transparent conductive film 105, the location corresponding to a location where the ridge structure RS of the transparent conductive film 105 and the second cladding layer 104 is to be formed (see FIG. 11). The resist pattern RP2 is formed by a technique similar to that of the resist pattern RP1.

Next, by using the resist pattern RP2 as a mask, at least part (for example, part) of the transparent conductive film 105 and the second cladding layer 104 in the thickness direction is etched by RIE or the like. As a result, the ridge structure RS is formed (see FIG. 12).

Next, the resist pattern RP2 is removed (see FIG. 13). Specifically, the resist pattern RP2 is removed by dry etching or wet etching similarly to the resist pattern RP1.

### <Step S25>

In step S25, fault suppression groove generation processing 2 (steps S25-1 to S25-9 in FIG. 24) is performed.

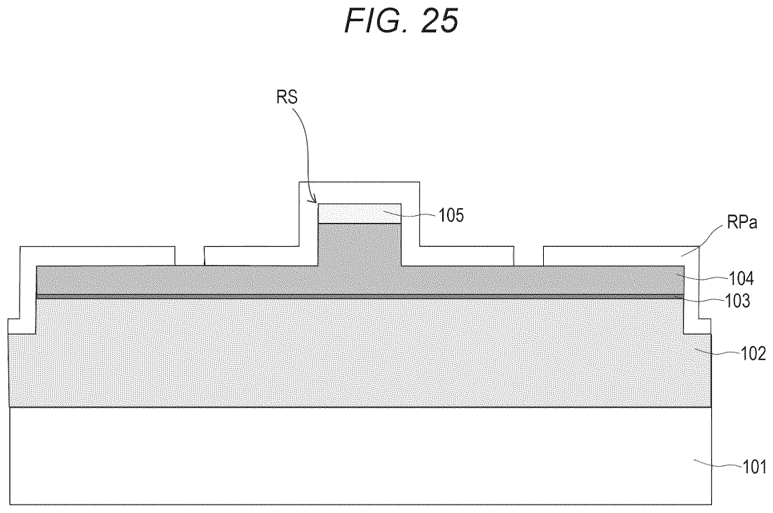

In the first step S25-1, a first resist pattern RPa is formed. Specifically, the resist pattern RPa is formed on the multilayer body on which the ridge structure RS is formed, the resist pattern RPa having openings at locations corresponding to a location where the first groove T1a on the outer side (most +X side) and the second groove T2a on the outer side (most −X side) of the multilayer body are to be formed (see FIG. 25). The resist pattern RPa is formed by a technique similar to those of the resist patterns RP1 to RP3 described above.

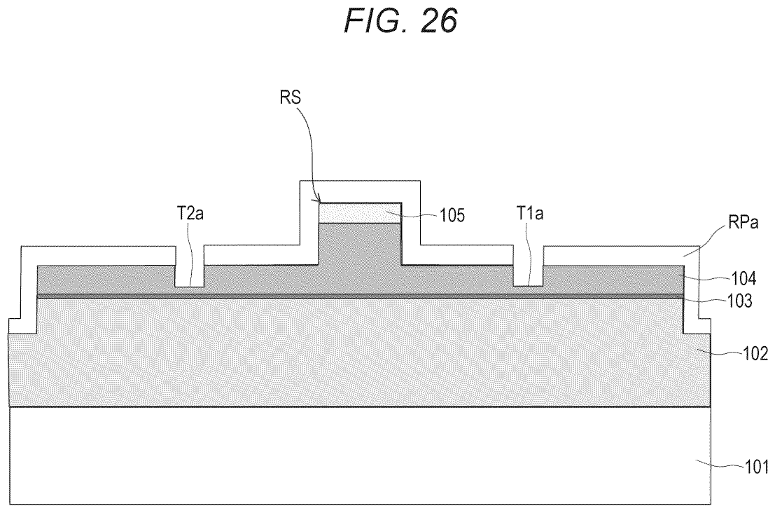

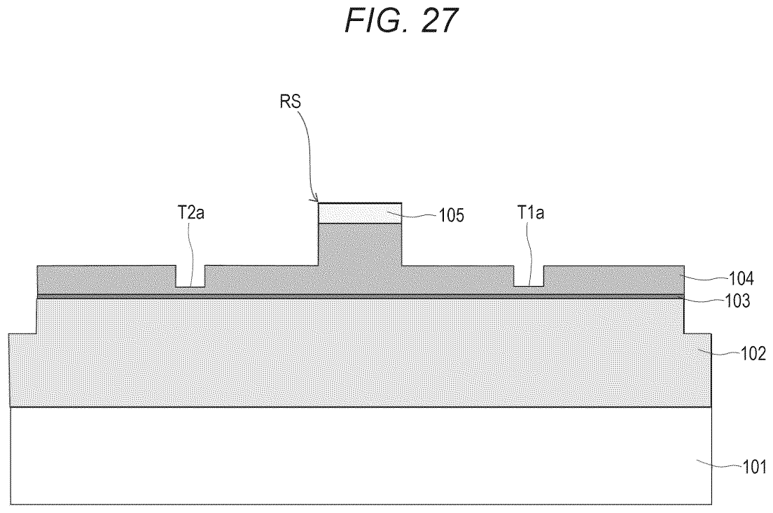

In the next step S25-2, the outer first and second grooves T1a and T2a are formed. Specifically, by using the first resist pattern RPa as a mask, the second cladding layer 104 is etched by the RIE method using a chlorine-based gas to simultaneously form the first and second grooves T1a and T2a having the same width and depth (see FIG. 26).

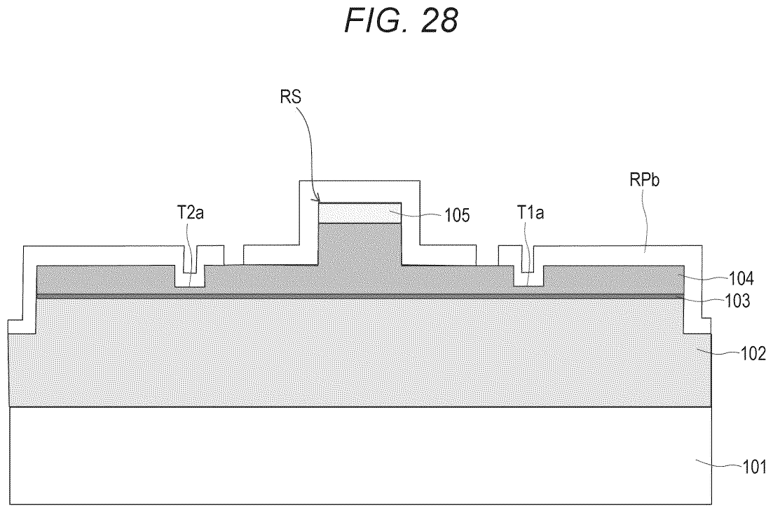

In the next step S25-3, the first resist pattern RPa is removed (see FIG. 27). Specifically, the first resist pattern RPa is removed by dry etching or wet etching similarly to the resist patterns RP1 to RP3 described above.

In the next step S25-4, a second resist pattern RPb is generated. Specifically, the second resist pattern RPb is formed on the multilayer body on which the ridge structure RS is formed and in which the first second grooves T1a and T2a are formed, the resist pattern RPb having openings at locations corresponding to locations where the intermediate first groove T1b and the intermediate second groove T2b of the multilayer body are to be formed (see FIG. 28). The resist pattern RPb is formed by a technique similar to those of the resist patterns RP1 to RP3 described above.

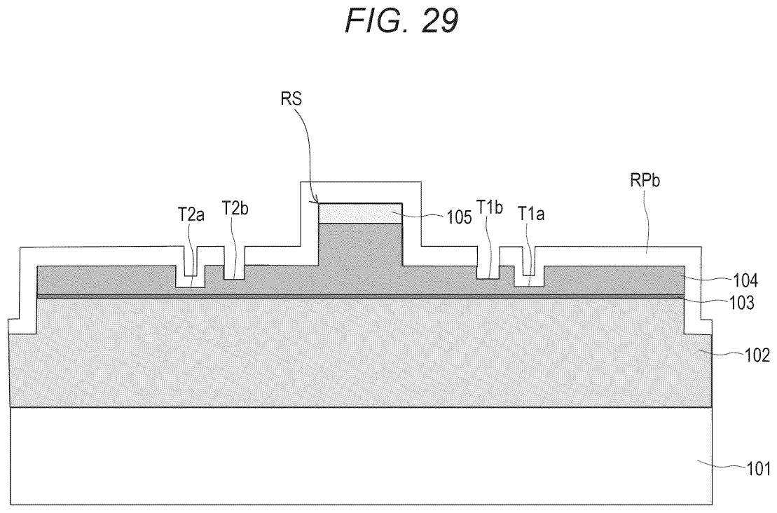

In the next step S25-5, the intermediate first and second grooves T1b and T2b are formed. Specifically, by using the second resist pattern RPb as a mask, the second cladding layer 104 is etched by the RIE method using a chlorine-based gas to simultaneously form the first and second grooves T1b and T2b having the same width and depth (see FIG. 29).

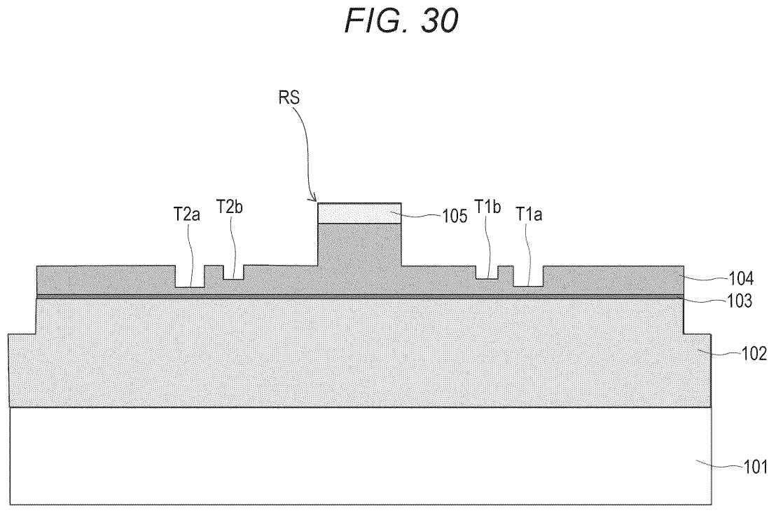

In the next step S25-6, the second resist pattern RPb is removed (see FIG. 30). Specifically, the second resist pattern RPb is removed by dry etching or wet etching similarly to the resist patterns RP1 to RP3 described above.

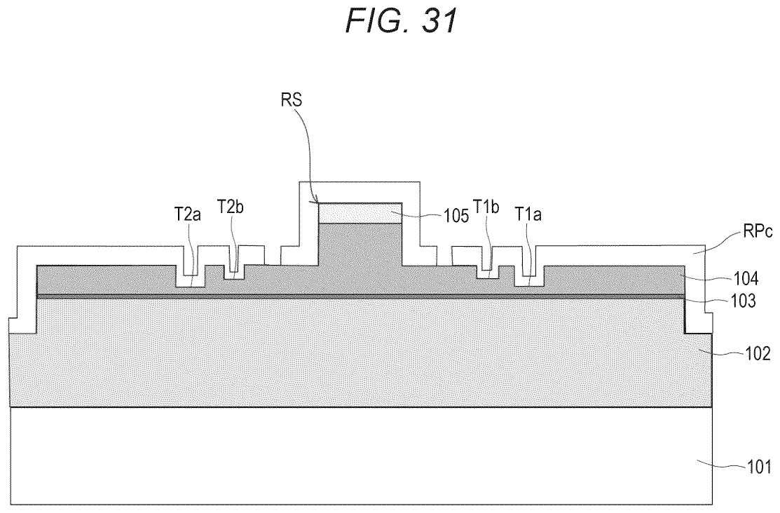

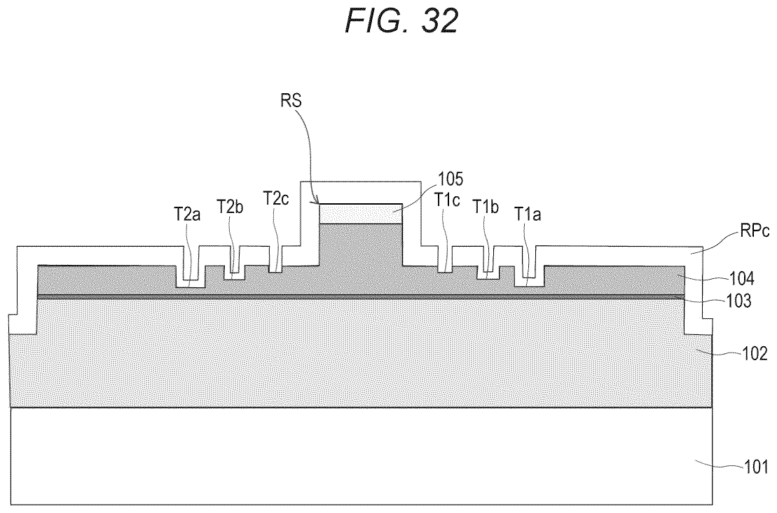

In the next step S25-7, a third resist pattern RPc is generated. Specifically, the resist pattern RPc is formed on the multilayer body on which the ridge structure RS is formed and in which the first grooves T1a and T1b and the second grooves T2a and T2b are formed, the resist pattern RPc having openings at locations corresponding to locations where the first groove T1c on the inner side (most −X side) and the second groove T2c on the outer side (most +X side) of the multilayer body are to be formed (see FIG. 31). The resist pattern RPc is formed by a technique similar to those of the resist patterns RP1 to RP3 described above.

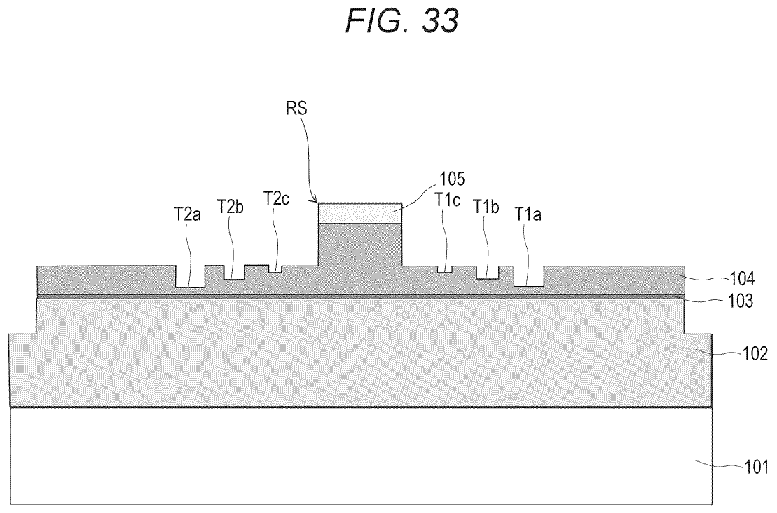

In the next step S25-8, the inner first and second grooves T1b and T2b are formed. Specifically, by using the third resist pattern RPc as a mask, the second cladding layer 104 is etched by the RIE method using a chlorine-based gas to simultaneously form the first and second grooves T1c and T2c having the same width and depth (see FIG. 32).

In the last step S25-9, the third resist pattern RPc is removed (see FIG. 33). Specifically, the third resist pattern RPc is removed by dry etching or wet etching similarly to the resist patterns RP1 to RP3 described above.

### <Step S26>

In step S26, the insulating layer 106 is formed. Specifically, the insulating layer 106 is formed on the multilayer body on which the ridge structure RS is formed and in which the first grooves T1a to T1c and the second grooves T2a to T2c are formed by a vapor deposition method, a sputtering method, or the like (see FIG. 17).

### <Step S27>

In step S7, the contact hole CH is formed. Specifically, the insulating layer 106 on the top portion of the ridge structure RS is removed by dry etching by the RIE method using a fluorine-based gas or wet etching using a hydrofluoric acid-based etchant. As a result, the contact hole CH is formed, and the top portion (for example, the transparent conductive film 105) of the ridge structure RS is exposed (see FIG. 18).

### <Step S28>

In step S28, the anode electrode 107 is formed. Specifically, first, the pad metal 107a is formed on the multilayer body on which the insulating layer 106 in which the contact hole CH is opened is formed (see FIG. 19). More specifically, a film of the material of the pad metal 107a is formed by a vapor deposition method, a sputtering method, or the like, and patterning is performed by a lift-off method, for example.

Next, the barrier metal 107b is formed on the pad metal 107a by a similar technique (see FIG. 20).

Next, the bonding metal 107c is formed on the barrier metal 107b by a similar technique (see FIG. 21).

### <Step S29>

In step S29, the cathode electrode 108 is formed (see FIG. 22).

Specifically, after the back surface of the substrate 101 is polished to a thickness suitable for cleavage, chipping, and mounting, the material of the cathode electrode 108 is formed on the back surface of the substrate 101 by a vapor deposition method or a sputtering method, and patterning is performed by lift-off, for example.

### <Step S30>

In step S30, cleavage is performed. Specifically, cleavage is performed in a bar shape so that the emission end surface (resonator end surface) is exposed similarly to step $10 of the first example described above.

### <Step S31>

In step S11, the end surface is coated. Specifically, the exposed end surface (cleavage plane) of each bar is coated in accordance with device characteristics. More specifically, a dielectric film such as Al₂O₃, SiO₂, or Si₃N₄ is formed with a predetermined thickness on the cleavage plane of each bar by a vapor deposition method or a sputtering method.

### <Step S32>

In step S12, cleavage is performed. Specifically, scribes are formed in each bar along the longitudinal direction of the ridge structure RS and the bar are divided into chips, thereby obtaining the chip-shaped semiconductor laser 100.

In the second example of the method for manufacturing the semiconductor laser 100 described above, it is necessary to perform etching every time each of the plurality of grooves having different widths and/or depths is formed, but the degree of freedom in selection and combination of the plurality of grooves having different widths and/or depths is higher than that in the first example of the method for manufacturing the semiconductor laser 100.

### (5) Effects of Semiconductor Laser and Method for Manufacturing the Same

Hereinafter, effects of the semiconductor laser 100 and the method for manufacturing the same according to the first embodiment of the present technology will be described.

The semiconductor laser 100 according to the first embodiment includes the resonator R having a multilayer structure including: the first cladding layer 102; the second cladding layer 104; and the active layer 103 disposed between the first cladding layer 102 and the second cladding layer 104; the multilayer structure including the pair of resonator end surfaces REF1 and REF2 facing each other. The resonator R has the ridge structure RS extending in the resonator length direction on the surface on the second cladding layer 104 side, and

the plurality of grooves is provided in each of the one side portion SP1 and the other side portion SP2 sandwiching the ridge structure RS in plan view in the surface of the resonator R on the second cladding layer 104 side.

In this case, due to the plurality of grooves, at the time of progress of cleavage, the progress speed of cleavage (transmission speed of stress) can be gradually reduced while the stress is absorbed, and concentration of the stress on the skirt portion of the ridge structure RS can be suppressed. Therefore, it is possible to suppress generation of a fault (step) starting from the skirt portion of the ridge structure RS in the vicinity of the resonator end surface.

As a result, according to the semiconductor laser 100 according to the first embodiment, it is possible to provide a semiconductor laser capable of suppressing a decrease in yield while suppressing an influence on laser characteristics.

In contrast, for example, as in a semiconductor laser 100C of a comparative example illustrated in FIG. 42, in a case where a plurality of grooves is not formed in the vicinity of resonator end surfaces of a resonator R on a +X side and/or a −X side of the ridge structure RS, when a resonator end surface is formed by cleavage, for example, stress concentrates on a skirt portion of the ridge structure in the vicinity of the resonator end surface, and a minute fault F (step) of several μm or less is generated from the skirt portion. If this step extends to a light emitting region LA of an active layer 103, reliability is deteriorated. As a result, the yield decreases.

Note that, even if a single groove is formed in the vicinity of the resonator end surfaces of the resonator R on the +X side and/or the −X side of the ridge structure RS, stress can be absorbed to some extent and the transmission speed thereof can be reduced. However, there is a risk that stress that cannot be absorbed by the groove may concentrate on the skirt portion of the ridge structure RS, there is a risk that a fault may occur, and there is a risk that a fault starting from the groove may occur.

For example, the semiconductor laser described in Patent Document 1 has a step confinement layer on a current path from an anode electrode to a light emitting region in a resonator, and thus has a considerable influence on laser characteristics (for example, light emission characteristics).

In contrast, since the semiconductor laser 100 according to the first embodiment does not have a special layer such as the above-described step confinement layer on the current path from the anode electrode 107 to the light emitting region LA in the resonator R, it is possible to suppress the influence on laser characteristics (for example, light emission characteristics).

In the semiconductor laser 100, in order to suppress the occurrence of a step starting from the ridge structure RS, the groove formed in the resonator R may not be deep enough to reach, for example, the active layer 103 or the first cladding layer 102. Therefore, the groove can be formed in a relatively short time, leading to improvement of manufacturing efficiency. The plurality of grooves is arranged in a direction intersecting the resonator length direction. Therefore, stress to concentrate on the ridge structure RS can be absorbed stepwise.

Each of the plurality of grooves extends substantially parallel to the resonator length direction. Therefore, the plurality of grooves can be efficiently laid out in each of the one side portion SP1 and the other side portion SP2.

The plurality of grooves is provided in part of each of the one side portion SP1 and the other side portion SP2 in the resonator length direction.

Specifically, the plurality of grooves (for example, the plurality of first grooves T1a to T1c ) is provided in a portion of at least one of the one side portion SP1 or the other side portion SP2 including the position of the resonator end surface REF1, which is one of the pair of resonator end surfaces REF1 and REF2. Therefore, it is possible to effectively suppress a step that can occur on the resonator end surface REF1. The plurality of grooves (for example, the plurality of second grooves T2a to T2c) is provided in a portion of at least one of the one side portion SP1 or the other side portion SP2 including the position of the resonator end surface REF2, which is the other of the pair of resonator end surfaces REF1 and REF2. Therefore, it is possible to effectively suppress a step that can occur on the resonator end surface REF2.

The plurality of first grooves T1a to T1c , which is the plurality of grooves, is provided in the one side portion SP1 of the surface of the resonator R on the first cladding layer 102 side, and the plurality of first grooves T1a to T1c have different widths and/or depths. Therefore, the plurality of first grooves T1a to T1c can have different functions.

The plurality of first grooves Ta to T1c is narrower as being closer to the ridge structure RS. Therefore, it is possible to suppress concentration of stress on the skirt portion of the ridge structure RS, and it is possible to suppress generation of a starting point of a fault in the vicinity of the ridge structure RS.

The plurality of first grooves Ta to T1c is shallower as being closer to the ridge structure RS. Therefore, it is possible to suppress concentration of stress on the skirt portion of the ridge structure RS, and it is possible to suppress generation of a starting point of a fault in the vicinity of the ridge structure RS.

The plurality of first grooves Ta to T1c is narrower and shallower as being closer to the ridge structure RS. Therefore, it is possible to sufficiently suppress concentration of stress on the skirt portion of the ridge structure RS, and it is possible to sufficiently suppress generation of a starting point of a fault in the vicinity of the ridge structure RS.

The plurality of second grooves T2a to T2c, which is the plurality of grooves, is provided in the other side portion SP2 of the surface of the resonator R on the first cladding layer 102 side, and the plurality of second grooves T2a to T2c have different widths and/or depths. Therefore, the plurality of second grooves T2a to T2c can have different functions.

The plurality of second grooves T2a to T2c is narrower as being closer to the ridge structure RS. Therefore, it is possible to suppress concentration of stress on the skirt portion of the ridge structure RS, and it is possible to suppress generation of a starting point of a fault in the vicinity of the ridge structure RS.

The plurality of second grooves T2a to T2c is shallower as being closer to the ridge structure RS. Therefore, it is possible to suppress concentration of stress on the skirt portion of the ridge structure RS, and it is possible to suppress generation of a starting point of a fault in the vicinity of the ridge structure RS.

The plurality of second grooves T2a to T2c is narrower and shallower as being closer to the ridge structure RS. Therefore, it is possible to sufficiently suppress concentration of stress on the skirt portion of the ridge structure RS, and it is possible to sufficiently suppress generation of a starting point of a fault in the vicinity of the ridge structure RS.

The method for manufacturing the semiconductor laser 100 according to the firs embodiment, the method including: a process of laminating the first cladding layer 102, the active layer 103, and the second cladding layer 104 in this order on the substrate 101 to generate the multilayer body L; a process of forming at least the ridge structure RS on a surface of the multilayer body L on the second cladding layer 104 side by etching the multilayer body L; a process of forming a plurality of grooves in at least one of the one side portion SP1 or the other side portion SP2 sandwiching the ridge structure RS in plan view in a surface of the multilayer body L on the second cladding layer 104 side; and a process of cleaving the multilayer body in which the plurality of grooves is formed and forming the emission end surfaces (resonator end surfaces REF1, REF2) orthogonal to the longitudinal direction of the ridge structure RS.

Therefore, it is possible to manufacture a semiconductor laser capable of suppressing a decrease in yield while suppressing an influence on laser characteristics.

In the process of forming the plurality of grooves, widths and/or depths of at least two grooves of the plurality of grooves are made different from each other. Therefore, it is possible to further suppress a decrease in yield.

### 3. Semiconductor Laser According to Second Embodiment of Present Technology

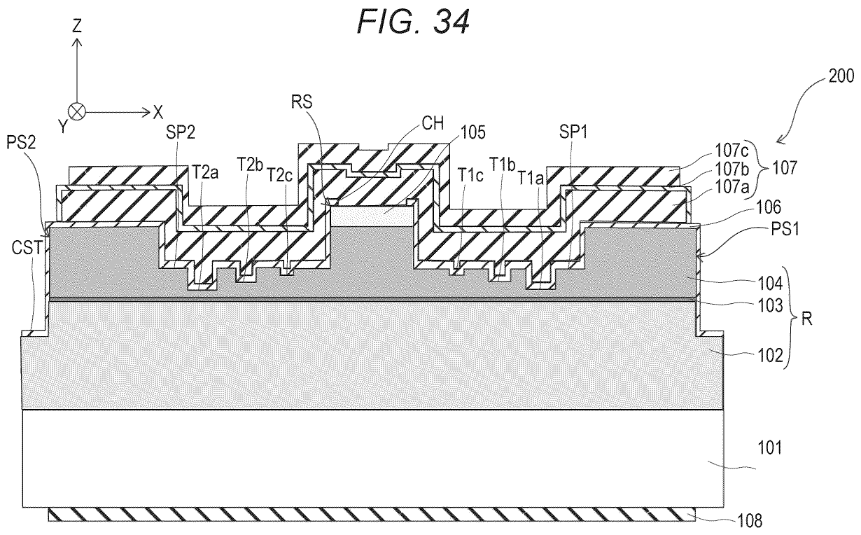

Hereinafter, a semiconductor laser 200 according to a second embodiment of the present technology will be described with reference to FIG. 34.

As illustrated in FIG. 34, the semiconductor laser 200 of the second embodiment has a configuration similar to that of the semiconductor laser 100 of the second embodiment except that the semiconductor laser 200 has first and second protective structures PS1 and PS2.

More specifically, in the semiconductor laser 200 according to the second embodiment, a resonator R has the first protective structure PS1 extending in the resonator length direction (Y-axis direction) on a side of one side portion SP1 opposite to a ridge structure RS side, and has a second protective structure PS2 extending in the resonator length direction (Y-axis direction) on a side of the other side portion SP2 opposite to a ridge structure RS side. The upper surfaces (+Z side surfaces) of the first and second protective structures PS1 and PS2 are substantially flush with an upper surface (+Z side surface) of a second cladding layer 104 of a ridge structure RS.

That is, the first and second protective structures PS1 and PS2 extend along the ridge structure RS at the same height as the ridge structure RS on the +X side and the −X side of the ridge structure RS, respectively, and have a function of protecting the ridge structure RS.

In the semiconductor laser 200, a plurality of first grooves T1a to T1c is located between the ridge structure RS and the first protective structure PSI in plan view. In the semiconductor laser 200, a plurality of second grooves T2a to T2c is located between the ridge structure RS and the second protective structure PS2 in plan view.

Also the semiconductor laser 200 can be manufactured by a manufacturing method according to the first example or the second example of the method for manufacturing the semiconductor laser 100 of the first embodiment.

In the method for manufacturing the semiconductor laser 200, in a process of forming at least the ridge structure RS, the first protective structure PSI extending in the resonator length direction on the side of the one side portion SP1 opposite to the ridge structure RS side, and the second protective structure PS2 extending in the resonator length direction on the side of the other side portion SP2 opposite to the ridge structure RS side are also formed.

### 4. Semiconductor Laser According to Third Embodiment of Present Technology

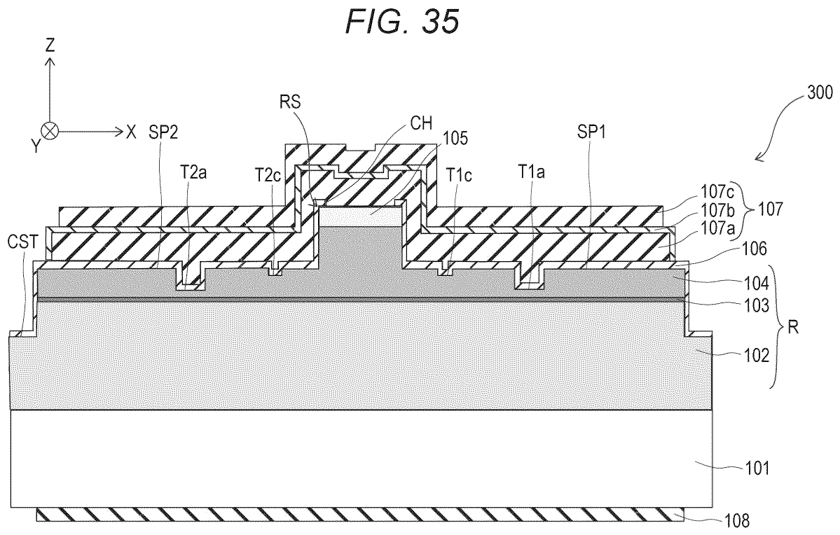

Hereinafter, a semiconductor laser 300 according to a third embodiment of the present technology will be described with reference to FIG. 35.

The semiconductor laser 300 of the third embodiment has a configuration similar to that of the semiconductor laser 100 of the first embodiment except that a first groove T1b is not provided in one side portion SP1 and a second groove T2b is not provided in the other side portion SP2.

In the semiconductor laser 300, although a fault suppression effect is slightly inferior to that of the semiconductor laser 100, a necessary fault suppression effect (capable of suppressing a decrease in yield) can be expected with a smaller number of grooves.

Also the semiconductor laser 300 can be manufactured by a manufacturing method according to the first example or the second example of the method for manufacturing the semiconductor laser 100 of the first embodiment. At this time, since the number of types of grooves is small, an etching process can be simplified.

### 5. Semiconductor Laser According to Fourth Embodiment of Present Technology

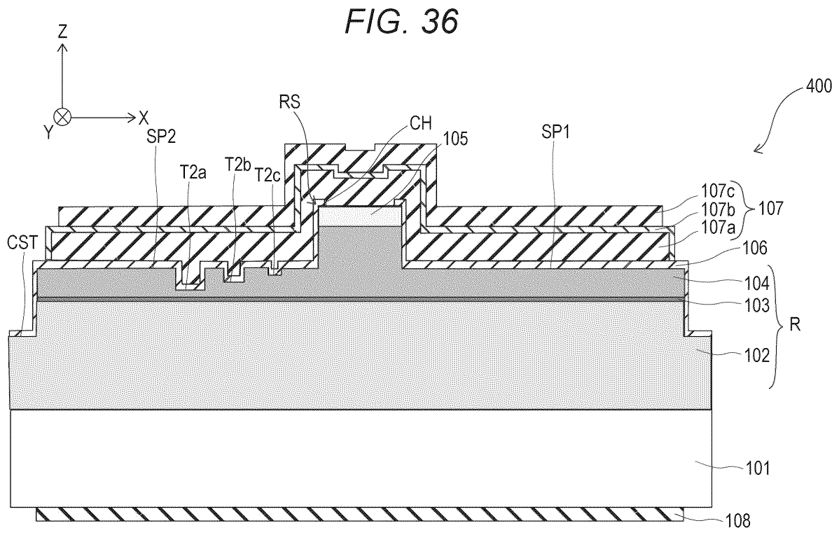

Hereinafter, a semiconductor laser 400 according to a fourth embodiment of the present technology will be described with reference to FIG. 36.

The semiconductor laser 400 of the fourth embodiment has a configuration similar to that of the semiconductor laser 100 of the first embodiment except that a plurality of first grooves T1a to T1c is not provided in one side portion SP1.

Incidentally, depending on the cleavage direction, it is assumed that stress is mainly applied to a ridge structure RS from one side (−X side or +X side).

Therefore, assuming a case where the semiconductor laser 400 is cleaved so that stress is mainly transmitted from the −X side to the ridge structure RS at the time of cleavage, a plurality of second grooves T2a to T2c is provided only on the −X side of the ridge structure RS.

In the semiconductor laser 400, in a case where the stress at the time of cleavage is mainly applied from one side of the ridge structure RS, a fault suppression effect (capable of suppressing a decrease in yield) can be expected.

Note that, assuming a case where cleavage is performed so that stress is mainly transmitted from the +X side to the ridge structure RS at the time of cleavage, the plurality of first grooves T1a to T1c may be provided only on the one side portion SP1. Also in this case, effects similar to those of the semiconductor laser 400 can be obtained.

Also the semiconductor laser 400 can be manufactured by a manufacturing method according to the first example or the second example of the method for manufacturing the semiconductor laser 100 of the first embodiment.

### 6. Semiconductor Laser According to Fifth Embodiment of Present Technology

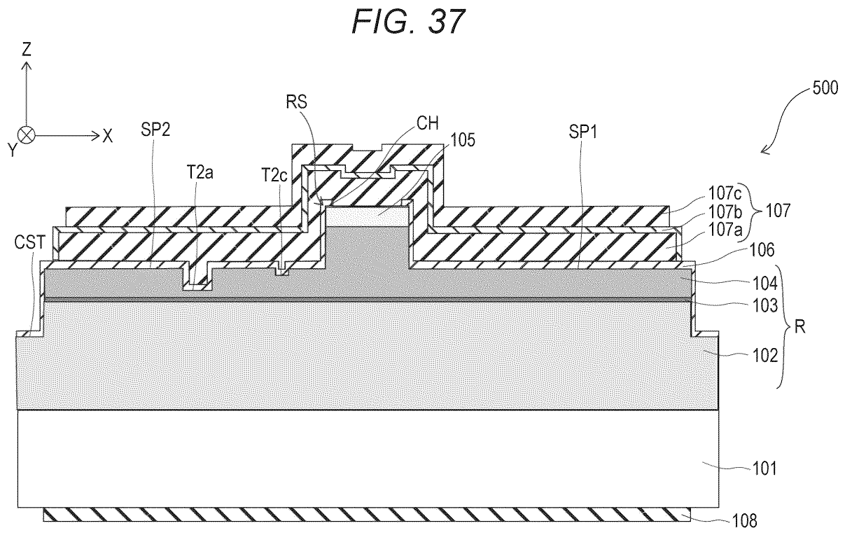

Hereinafter, a semiconductor laser 500 according to a fifth embodiment of the present technology will be described with reference to FIG. 37.

The semiconductor laser 500 of the fifth embodiment has a configuration similar to that of the semiconductor laser 400 of the fourth embodiment except that a second groove T2b is not provided in the other side portion SP2.

In the semiconductor laser 500, although a fault suppression effect is slightly inferior to that of the semiconductor laser 400 of the fourth embodiment, a necessary fault suppression effect (capable of suppressing a decrease in yield) can be expected with a smaller number of grooves. Also the semiconductor laser 500 can be manufactured by a manufacturing method according to the first example or the second example of the method for manufacturing the semiconductor laser 100 of the first embodiment.

### 7. Semiconductor Laser According to Sixth Embodiment of Present Technology

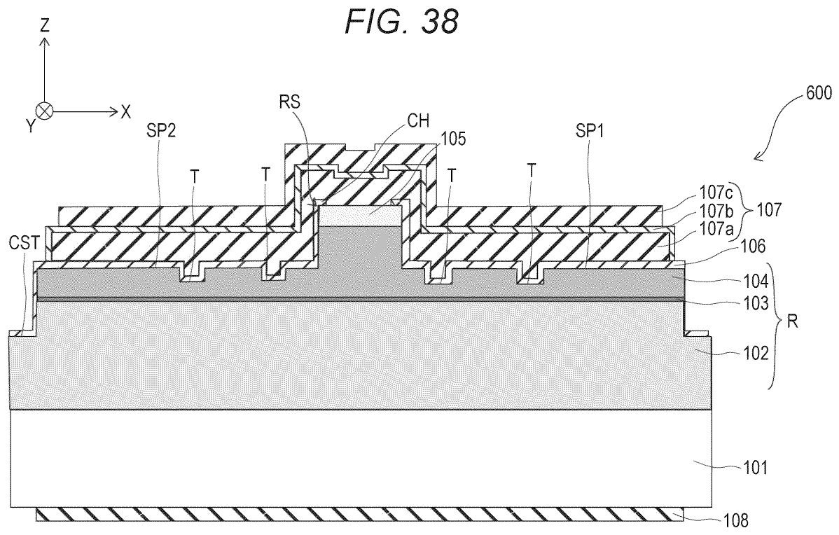

Hereinafter, a semiconductor laser 600 according to a sixth embodiment of the present technology will be described with reference to FIG. 38.

The semiconductor laser 600 of the sixth embodiment has a configuration similar to the semiconductor laser 100 of the first embodiment except that a plurality of (for example, two) grooves T having the same width and depth is provided in one side portion SP1, and a plurality of (for example, two) grooves T having the same width and depth is provided in the other side portion SP2. The grooves T provided in the one side portion SP1 and the grooves T provided in the other side portion SP2 have the same width and depth.

In the semiconductor laser 600, although a fault suppression effect is slightly inferior to that of the semiconductor laser 100 of the first embodiment, a necessary fault suppression effect (capable of suppressing a decrease in yield) can be expected with a smaller number of grooves.

Also the semiconductor laser 600 can be manufactured by a manufacturing method according to the first example of the method for manufacturing the semiconductor laser 100 of the first embodiment. At this time, since the widths and depths of all the grooves T are the same, all the grooves T can be simultaneously formed by one etching.

### 8. Semiconductor Laser According to Seventh Embodiment of Present Technology

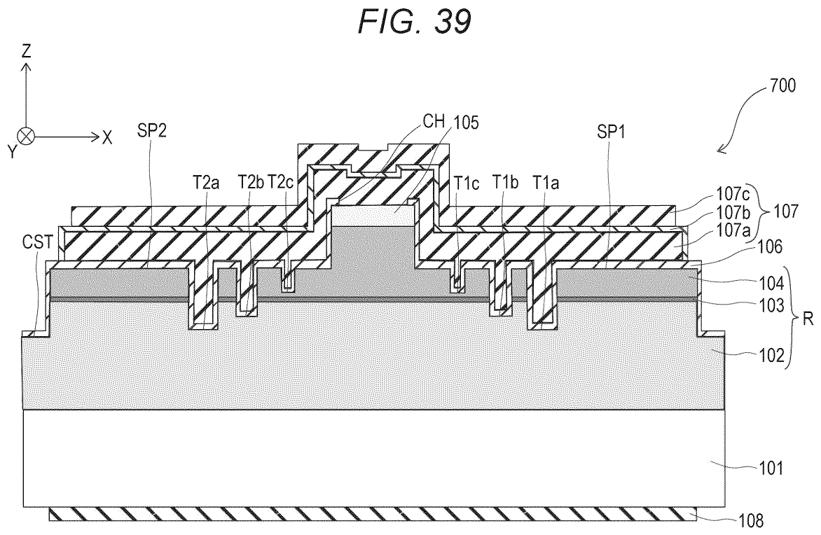

Hereinafter, a semiconductor laser 700 according to a seventh embodiment of the present technology will be described with reference to FIG. 39.

The semiconductor laser 700 of the seventh embodiment has a configuration similar to that of the semiconductor laser 100 of the first embodiment except that first grooves T1a to T1c and second grooves T2a to T2c are deeper than the corresponding grooves of the semiconductor laser 100.

In the semiconductor laser 700, the bottom surfaces of the first groove T1c and the second groove T2c are located near an active layer 103 in a second cladding layer 104, and the bottom surfaces of the first grooves T1a and T1b and the second grooves T2a and T2b are located in a first cladding layer 102.

In the semiconductor laser 700, it is possible to expect an effect of suppressing generation of a fault due to stress from a deeper direction compared with the semiconductor laser 100 of the first embodiment. Also the semiconductor laser 700 can be manufactured by a manufacturing method according to the first example or the second example of the method for manufacturing the semiconductor laser 100 of the first embodiment.

### 9. Modifications of Present Technology

The present technology is not limited to the embodiments described above, and various modifications can be made.

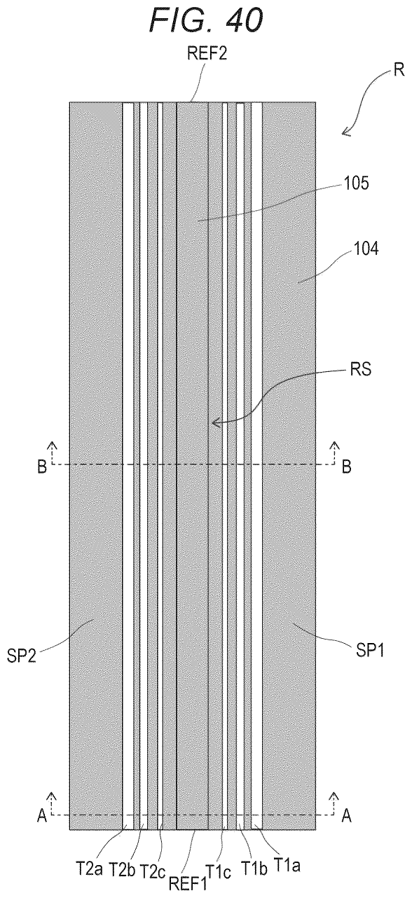

For example, like a resonator R of a semiconductor laser of Modification 1 illustrated in FIG. 40, a plurality of first grooves T1a to T1c and a plurality of second grooves T2a to T2c may extend over the entire region in the resonator length direction.

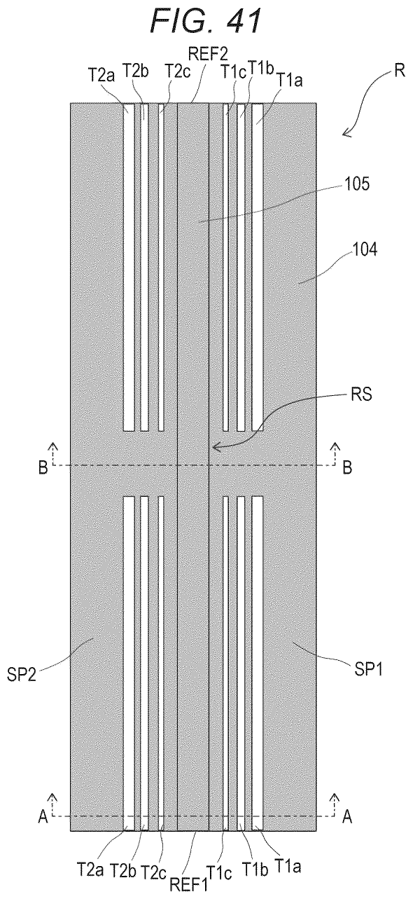

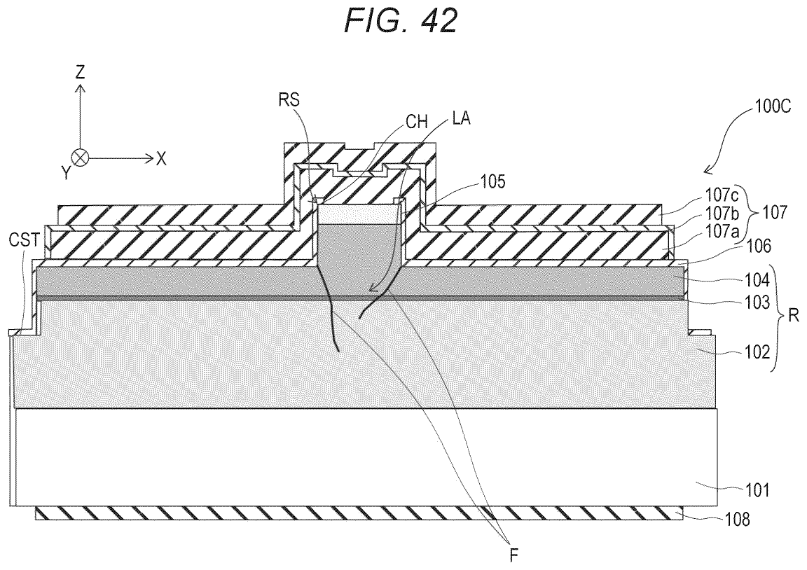

For example, like a resonator R of a semiconductor laser of Modification 2 illustrated in FIG. 41, a plurality of first grooves T1a to T1c and a plurality of second grooves T2a to T2c may extend over the region except the central portion in the resonator length direction.

For example, four or more grooves may be provided in one side portion SP1, or four or more grooves may be provided in the other side portion SP2.

For example, a ridge structure RS may not include a transparent conductive film 105.

For example, an anode wiring line may have a two-layer structure or a single layer structure.

For example, a semiconductor laser according to the present technology may include a plurality of resonators R. A semiconductor laser according to the present technology may include, for example, a plurality of resonators R on a same substrate 101.

For example, in the semiconductor laser of each of the embodiments described above, the resonator end surface is formed by cleavage, but may be formed by, for example, dicing, etching (for example, dry etching), or the like. For example, even in a case where the resonator end surface is formed by dicing, dry etching, or the like, by providing a plurality of grooves in at least one of one side portion SP1 or the other side portion SP2, it is possible to suppress the occurrence of a fault starting from a skirt portion of a ridge structure RS, and eventually, it is possible to suppress a decrease in yield.

Some of the configurations of the semiconductor laser of each of the embodiments and modifications described above may be combined within a range in which they do not contradict each other.

In each embodiment and each modification described above, the material, conductivity type, thickness, numerical value, and the like of each layer constituting the semiconductor laser can be appropriately changed within a range functioning as a semiconductor laser.

### 10. Application Example to Electronic Apparatus

The technology according to the present disclosure (the present technology) can be applied to various products (electronic apparatuses). For example, the technology according to the present disclosure may be realized as a device mounted on any type of a mobile body such as an automobile, an electric car, a hybrid electric car, a motorcycle, a bicycle, a personal mobility vehicle, an airplane, a drone, a ship, or a robot.

The semiconductor laser according to the present technology can also be applied as, for example, a light source of an apparatus that forms or displays an image by laser light (for example, a laser printer, a laser copier, a projector, a head-mounted display, a head-up display, or the like).

### 11. Example in Which Semiconductor Laser is Applied to Distance Measuring Device

Hereinafter, application examples of the semiconductor laser according to each of the embodiments and modifications described above will be described.

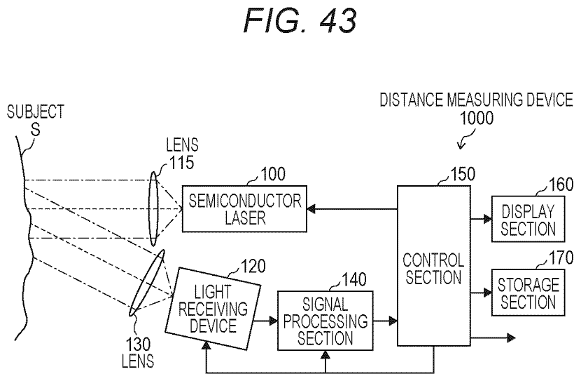

FIG. 43 illustrates an example of a schematic configuration of a distance measuring device 1000 including the semiconductor laser 100 as an example of an electronic apparatus according to the present technology. The distance measuring device 1000 measures a distance to a subject S by a time of flight (TOF) method. The distance measuring device 1000 includes the semiconductor laser 100 as a light source. The distance measuring device 1000 includes, for example, the semiconductor laser 100, a light receiving device 120, lenses 115 and 130, a signal processing section 140, a control section 150, a display section 160, and a storage section 170.

The light receiving device 120 detects light reflected by the subject S. The lens 115 is a lens for collimating light emitted from the semiconductor laser 100, and is a collimating lens. The lens 130 is a lens for condensing light reflected by the subject S and guiding the light to the light receiving device 120, and is a condenser lens.

The signal processing section 140 is a circuit for generating a signal corresponding to a difference between a signal input from the light receiving device 120 and a reference signal input from the control section 150. The control section 150 includes, for example, a time-to-digital converter (TDC). The reference signal may be a signal input from the control section 150, or may be an output signal of a detection section that directly detects the output of the semiconductor laser 100. The control section 150 is, for example, a processor that controls the semiconductor laser 100, the light receiving device 120, the signal processing section 140, the display section 160, and the storage section 170. The control section 150 is a circuit that measures a distance to the subject S on the basis of a signal generated by the signal processing section 140. The control section 150 generates a video signal for displaying information about a distance to the subject S, and outputs the video signal to the display section 160. The display section 160 displays information about the distance to the subject S, on the basis of the video signal input from the control section 150. The control section 150 stores information about the distance to the subject S in the storage section 170.

In the present application example, instead of the semiconductor laser 100, any one of the semiconductor lasers 200, 300, 400, 500, 600, and 700 described above can be applied to the distance measuring device 1000.

### 12. Example in Which Distance Measuring Device is Mounted on Mobile Body

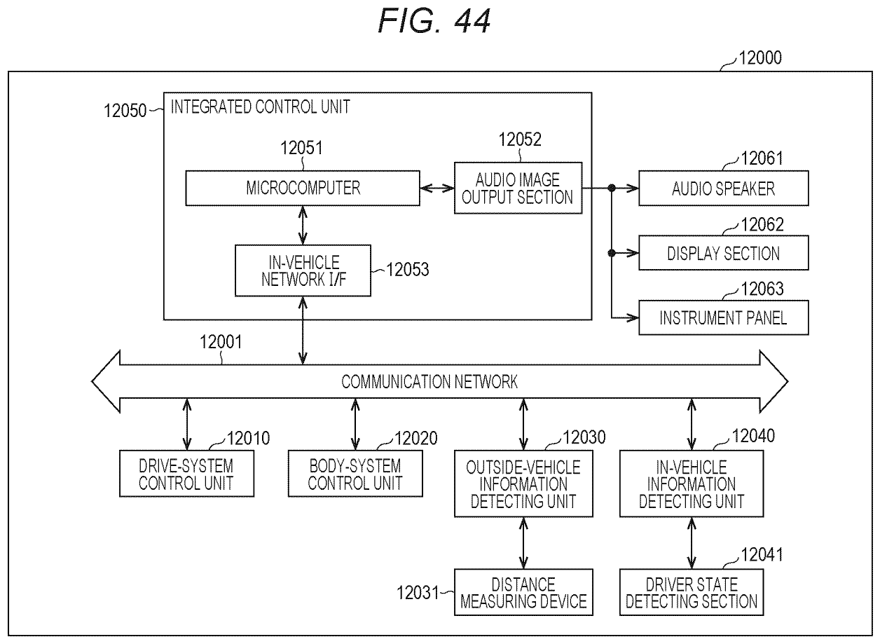

FIG. 44 is a block diagram illustrating an example of schematic configuration of a vehicle control system as an example of a mobile body control system to which the technology according to the present disclosure can be applied.

A vehicle control system 12000 includes a plurality of electronic control units connected to each other via a communication network 12001. In the example illustrated in FIG. 44, the vehicle control system 12000 includes a drive-system control unit 12010, a body-system control unit 12020, an outside-vehicle information detecting unit 12030, an in-vehicle information detecting unit 12040, and an integrated control unit 12050. Furthermore, as a functional configuration of the integrated control unit 12050, a microcomputer 12051, an audio image output section 12052, and an in-vehicle network interface (I/F) 12053 are illustrated.

The drive-system control unit 12010 controls the operation of devices related to the drive system of the vehicle in accordance with various kinds of programs. For example, the drive-system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body-system control unit 12020 controls the operation of various kinds of devices provided to a vehicle body in accordance with various kinds of programs. For example, the body-system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body-system control unit 12020. The body-system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, a distance measuring device 12031 is connected to the outside-vehicle information detecting unit 12030. The distance measuring device 12031 includes the above-described distance measuring device 1000. The outside-vehicle information detecting unit 12030 causes the distance measuring device 12031 to measure a distance to an object (the subject S) outside the vehicle, and acquires distance data obtained by the measurement. The outside-vehicle information detecting unit 12030 may perform object detection processing of a person, a car, an obstacle, a sign, or the like on the basis of the acquired distance data.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041 may include, for example, a camera that images the driver, and, on the basis of detection information input from the driver state detecting section 12041, the in-vehicle information detecting unit 12040 may calculate a degree of fatigue or a degree of concentration of the driver, or may determine whether or not the driver is dozing off.

The microcomputer 12051 can calculate a control target value for the driving force generating device, the steering mechanism, or the braking device on the basis of the information about the inside or outside of the vehicle acquired by the outside-vehicle information detecting unit 12030 or the in-vehicle information detecting unit 12040, and output a control command to the drive-system control unit 12010. For example, the microcomputer 12051 can perform cooperative control intended to implement functions of an advanced driver assistance system (ADAS), the functions including: collision avoidance or shock mitigation for the vehicle; follow-up traveling based on an inter-vehicle distance; vehicle speed maintaining traveling; vehicle collision warning; and vehicle lane departure warning.

Furthermore, the microcomputer 12051 can perform cooperative control intended for automated driving, in which the vehicle travels in an automated manner without depending on operation of the driver, or the like, by controlling the driving force generating device, the steering mechanism, the braking device, or the like on the basis of information about the vehicle's surroundings acquired by the outside-vehicle information detecting unit 12030 or the in-vehicle information detecting unit 12040.

Furthermore, the microcomputer 12051 can output a control command to the body-system control unit 12020 on the basis of information about the outside of the vehicle acquired by the outside-vehicle information detecting unit 12030. For example, the microcomputer 12051 can perform cooperative control intended to prevent a glare, such as switching from a high beam to a low beam by controlling the headlamp in accordance with the position of a preceding vehicle or an oncoming vehicle detected by the outside-vehicle information detecting unit 12030.

The audio image output section 12052 transmits an output signal of at least one of audio or an image to an output device capable of visually or aurally notifying a passenger or the outside of the vehicle of information. In the example of FIG. 44, an audio speaker 12061, a display section 12062, and an instrument panel 12063 are illustrated as examples of the output device. For example, the display section 12062 may include at least one of an on-board display or a head-up display.

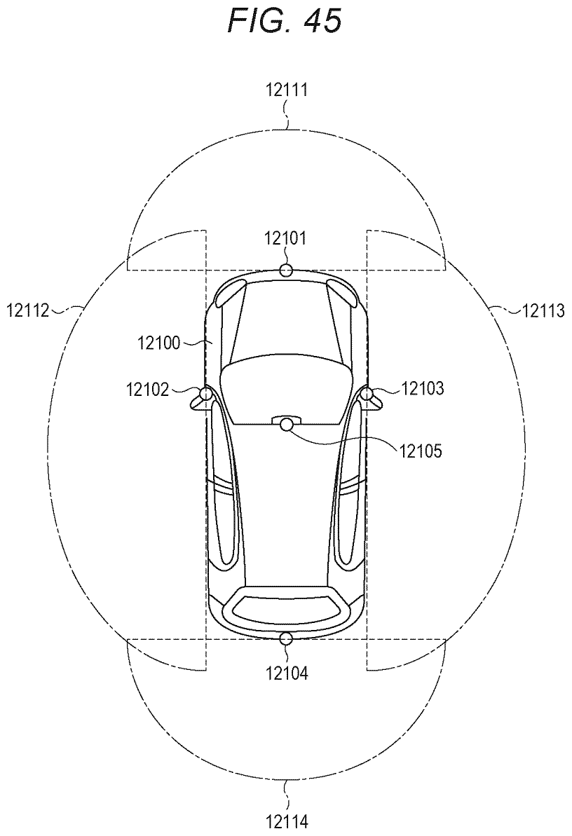

FIG. 45 is a view illustrating an example of an installation position of the distance measuring device 12031.

In FIG. 45, a vehicle 12100 includes distance measuring devices 12101, 12102, 12103, 12104, and 12105 as the distance measuring device 12031.

The distance measuring devices 12101, 12102, 12103, 12104, and 12105 are provided at positions such as, for example, a front nose, side mirrors, a rear bumper, a back door, and an upper part of a windshield in a vehicle cabin, of the vehicle 12100. The distance measuring device 12101 provided on the front nose and the distance measuring device 12105 provided on the upper part of the windshield in the vehicle cabin mainly acquire data of the front of the vehicle 12100. The distance measuring devices 12102 and 12103 provided in the side mirrors mainly acquire data of sides of the vehicle 12100. The distance measuring device 12104 provided in the rear bumper or the back door mainly acquires data of the rear of the vehicle 12100. The data of the front acquired by the distance measuring devices 12101 and 12105 is mainly used for detecting a preceding vehicle, a pedestrian, an obstacle, a traffic light, a traffic sign, or the like.

Note that FIG. 45 illustrates an example of detection ranges of the distance measuring devices 12101 to 12104. A detection range 12111 indicates a detection range of the distance measuring device 12101 provided on the front nose, detection ranges 12112 and 12113 indicate detection ranges of the distance measuring devices 12102 and 12103 provided in the side mirrors, respectively, and a detection range 12114 indicates a detection range of the distance measuring device 12104 provided in the rear bumper or the back door.

For example, the microcomputer 12051 can determine a distance to each three-dimensional object within the detection ranges 12111 to 12114 and a temporal change in the distance (a relative speed with respect to the vehicle 12100) on the basis of the distance data obtained from the distance measuring devices 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Moreover, the microcomputer 12051 can set an inter-vehicle distance to be secured from a preceding vehicle in advance, and perform automatic brake control (including follow-up stop control), automatic acceleration control (including follow-up start control), and the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance data obtained from the distance measuring devices 12101 to 12104, extract the classified three-dimensional object data, and use the extracted three-dimensional object data for automatic avoidance of an obstacle. For example, the microcomputer 12051 distinguishes obstacles around the vehicle 12100 into obstacles that are visible to the driver of the vehicle 12100 and obstacles that are difficult to see. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the drive-system control unit 12010. The microcomputer 12051 can thereby assist in driving to avoid collision.

An example of the mobile body control system to which the technology according to the present disclosure can be applied has been described above. The technology according to the present disclosure can be applied to the distance measuring device 12031 among the configurations described above.

The specific numerical values, shapes, materials (including compositions), and the like described in the present description are merely examples, and are not limited thereto.

Furthermore, the present technology can also have the following configurations.

(1) A semiconductor laser including a resonator having a multilayer structure including:
a first cladding layer;
a second cladding layer; and
an active layer disposed between the first cladding layer and the second cladding layer,
the multilayer structure including a pair of resonator end surfaces facing each other,
the resonator having a ridge structure extending in a resonator length direction on a surface of a second cladding layer side, and
a plurality of grooves being provided in at least one of one side portion or the other side portion sandwiching the ridge structure in plan view on the surface of the resonator on the second cladding layer side.

(2) The semiconductor laser according to (1), in which the plurality of grooves is arranged in a direction intersecting the resonator length direction.

(3) The semiconductor laser according to (1) or (2), in which each of the plurality of grooves extends substantially parallel to the resonator length direction.

(4) The semiconductor laser according to any one of (1) to (3), in which the plurality of grooves is provided in at least part of at least one of the one side portion or the other side portion in the resonator length direction.

(5) The semiconductor laser according to any one of (1) to (4), in which the plurality of grooves includes the groove provided in at least a portion of at least one of the one side portion and the other side portion including a position of one of the pair of resonator end surfaces.

(6) The semiconductor laser according to any one of (1) to (5), in which the plurality of grooves includes the groove provided in at least a portion of at least one of the one side portion or the other side portion including a position of the other of the pair of resonator end surfaces.

(7) The semiconductor laser according to any one of (1) to (6), in which a plurality of first grooves, which is the plurality of grooves, is provided in the one side portion, and at least two first grooves of the plurality of first grooves have different widths and/or depths.

(8) The semiconductor laser according to (7), in which the at least two first grooves are narrower as being closer to the ridge structure.

(9) The semiconductor laser according to (7) and (8), in which the at least two first grooves are shallower as being closer to the ridge structure.

(10) The semiconductor laser according to any one of (7) to (9), in which the at least two first grooves are narrower and shallower as being closer to the ridge structure.

(11) The semiconductor laser according to any one of (1) to (10), in which a plurality of second grooves, which is the plurality of grooves, is provided in the other side portion, and at least two second grooves of the plurality of second grooves have different widths and/or depths.

(12) The semiconductor laser according to (11), in which the at least two second grooves are narrower as being closer to the ridge structure.

(13) The semiconductor laser according to (11) or (12), in which the at least two second grooves are shallower as being closer to the ridge structure.

(14) The semiconductor laser according to any one of (11) to (13), in which the at least two second grooves are narrower and shallower as being closer to the ridge structure.

(15) The semiconductor laser according to any one of (1) to (14), in which bottom surfaces of the plurality of grooves are all located in the second cladding layer.

(16) The semiconductor laser according to any one of (1) to (15), in which the resonator has a first protective structure extending in the resonator length direction on a side of the one side portion opposite to a ridge structure side, and a second protective structure extending in the resonator length direction on a side of the other side portion opposite to a ridge structure side.

(17) The semiconductor laser according to any one of (1) to (16) further including a plurality of the resonators.

(18) An electronic apparatus including the semiconductor laser according to any one of (1) to (17). (19) A method for manufacturing a semiconductor laser, the method including:
a process of laminating a first cladding layer, an active layer, and a second cladding layer in this order on a substrate to generate a multilayer body;
a process of forming at least a ridge structure on a surface of the multilayer body on a second cladding layer side by etching the multilayer body;
a process of forming a plurality of grooves in at least one of one side portion or the other side portion sandwiching the ridge structure in plan view on the surface of the multilayer body on the second cladding layer side; and
a process of forming an emission end surface orthogonal to a longitudinal direction of the ridge structure on the multilayer body in which the plurality of grooves is formed.

(20) The method for manufacturing the semiconductor laser according to (19), in which in the process of forming the plurality of grooves, widths and/or depths of at least two grooves of the plurality of grooves are made different from each other.

(21) The method for manufacturing the semiconductor laser according to (19) or (20), in which in the process of forming at least the ridge structure, a first protective structure extending in the longitudinal direction on a side of the one side portion opposite to a ridge structure side, and a second protective structure extending in the longitudinal direction on a side of the other side portion opposite to a ridge structure side are also formed.

### REFERENCE SIGNS LIST

100, 200, 300, 400, 500, 600, 700 Semiconductor laser
101 Substrate
102 First cladding layer
103 Active layer
104 Second cladding layer
1000 Distance measuring device (electronic apparatus)
R Resonator
RS Ridge structure
REF1, REF2 Resonator end surface
SP1 One side portion
SP2 Other side portion
T1a, T1b, T1c First groove (groove)
T2a, T2b, T2c Second groove (groove)
PS1 First protective structure
PS2 Second protective structure

1. A semiconductor laser comprising a resonator having a multilayer structure including:
a first cladding layer;
a second cladding layer; and
an active layer disposed between the first cladding layer and the second cladding layer,
the multilayer structure including a pair of resonator end surfaces facing each other,
the resonator having a ridge structure extending in a resonator length direction on a surface on a second cladding layer side, and
a plurality of grooves being provided in at least one of one side portion or another side portion sandwiching the ridge structure in plan view on the surface of the resonator on the second cladding layer side.

2. The semiconductor laser according to claim 1, wherein the plurality of grooves is arranged in a direction intersecting the resonator length direction.

3. The semiconductor laser according to claim 2, wherein each of the plurality of grooves extends substantially parallel to the resonator length direction.

4. The semiconductor laser according to claim 3, wherein the plurality of grooves is provided in at least part of at least one of the one side portion or the another side portion in the resonator length direction.

5. The semiconductor laser according to claim 4, wherein the plurality of grooves includes the groove provided in at least a portion of at least one of the one side portion or the another side portion including a position of one of the pair of resonator end surfaces.

6. The semiconductor laser according to claim 4, wherein the plurality of grooves includes the groove provided in at least a portion of at least one of the one side portion or the another side portion including a position of another of the pair of resonator end surfaces.

7. The semiconductor laser according to claim 2, wherein a plurality of first grooves, which is the plurality of grooves, is provided in the one side portion, and at least two first grooves of the plurality of first grooves have different widths and/or depths.

8. The semiconductor laser according to claim 7, wherein the at least two first grooves are narrower as being closer to the ridge structure.

9. The semiconductor laser according to claim 7, wherein the at least two first grooves are shallower as being closer to the ridge structure.

10. The semiconductor laser according to claim 7, wherein the at least two first grooves are narrower and shallower as being closer to the ridge structure.

11. The semiconductor laser according to claim 7, wherein a plurality of second grooves, which is the plurality of grooves, is provided in the another side portion, and at least two second grooves of the plurality of second grooves have different widths and/or depths.

12. The semiconductor laser according to claim 11, wherein the at least two second grooves are narrower as being closer to the ridge structure.

13. The semiconductor laser according to claim 11, wherein the at least two second grooves are shallower as being closer to the ridge structure.

14. The semiconductor laser according to claim 11, wherein the at least two second grooves are narrower and shallower as being closer to the ridge structure.

15. The semiconductor laser according to claim 1, wherein the resonator has a first protective structure extending in the resonator length direction on a side of the one side portion opposite to a ridge structure side, and a second protective structure extending in the resonator length direction on a side of the another side portion opposite to a ridge structure side.

16. The semiconductor laser according to claim 1 further comprising a plurality of the resonators.

17. An electronic apparatus comprising the semiconductor laser according to claim 1.

18. A method for manufacturing a semiconductor laser, the method comprising:
a process of laminating a first cladding layer, an active layer, and a second cladding layer in this order on a substrate to generate a multilayer body;
a process of forming at least a ridge structure on a surface of the multilayer body on a second cladding layer side by etching the multilayer body;
a process of forming a plurality of grooves in at least one of one side portion or another side portion sandwiching the ridge structure in plan view on a surface of the multilayer body on the second cladding layer side; and
a process of forming an emission end surface orthogonal to a longitudinal direction of the ridge structure on the multilayer body in which the plurality of grooves is formed.

19. The method for manufacturing the semiconductor laser according to claim 18, wherein in the process of forming the plurality of grooves, widths and/or depths of at least two grooves of the plurality of grooves are made different from each other.

20. The method for manufacturing the semiconductor laser according to claim 18, wherein in the process of forming at least the ridge structure, a first protective structure extending in the longitudinal direction on a side of the one side portion opposite to a ridge structure side, and a second protective structure extending in the longitudinal direction on a side of the another side portion opposite to a ridge structure side are also formed.
